(19) United States
(12) Patent Application Publication
(10) Pub. No.: US 2025/0364312 A1
(43) Pub. Date: Nov. 27, 2025

(54) METHOD FOR FORMING A SEMICONDUCTOR DEVICE AND DEVICES FABRICATED THEREOF

(71) Applicant: TAIWAN SEMICONDUCTOR MANUFACTURING COMPANY, LTD., Hsinchu (TW)

(72) Inventors: Chun-Fu KUO, Hsinchu (TW); Kuan-Da HUANG, Hsinchu (TW); Chao-Hsien HUANG, Hsinchu (TW); Li-Te LIN, Hsinchu (TW)

(21) Appl. No.: 19/293,122

(22) Filed: Aug. 7, 2025

Related U.S. Application Data
(63) Continuation of application No. 18/231,320, filed on Aug. 8, 2023.
(60) Provisional application No. 63/461,986, filed on Apr. 26, 2023.

(51) Int. Cl. H01L 21/762; H01L 21/308; H01L 21/311; H10D 30/43; H10D 30/67; H10D 62/10; H10D 64/01; H10D 64/23; H10D 84/83

(52) U.S. Cl. CPC H01L 21/76224; H01L 21/308; H01L 21/311; H10D 30/43; H10D 30/6735; H10D 62/121; H10D 64/015; H10D 64/258; H10D 84/83

(57) ABSTRACT

Embodiments of the present disclosure provide a protective layer deposited over bottom structures to protect the bottom structure during fabrication of upper structures. The protective layer may prevent STI loss and bottom spacer loss during source/drain etch back process. The protective layer may also improve process uniformity by also eliminate process loading or non-uniformity in the STI loss, fin sidewall spacer height, and recess profiles. The protective layer may also slow down fin sidewall spacer etching rate during semiconductor fin etch back, thus, improving source/drain regions profile control.

### CROSS-REFERENCE TO RELATED APPLICATIONS

This application is a continuation application of U.S. patent application Ser. No. 18/231,320, filed Aug. 8, 2023, which claims priority to the U.S. Provisional Patent Application Ser. No. 63/461,986, filed Apr. 26, 2023. Each of the aforementioned applications is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area.

During semiconductor fabrication, etch back processes are used to form various structures. For example, an etch back process is used to form a protective layer on bottom materials/structures, e.g., shallow trench isolation (STI). The STI prevents the bottom materials/structures from being damaged during removing or patterning other areas, e.g., during partial removal of semiconductor stack during fabrication of a nanosheet device.

As minimum feature size reduces, the protective layer resulting from etch back process may also reduce sizes and does not provide sufficient protection to the bottom materials/structures during subsequent removal and patterning processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2-7, 7A-7B, 8, 8A-8B, 9-12, 12A-12G, 13-15, 15A-15E, 16, and 16A-E schematically illustrate various stages of manufacturing a semiconductor device according to embodiments of the present disclosure.

FIG. 17 is a flow chart of a method for manufacturing of a semiconductor device according to embodiments of the present disclosure.

FIGS. 18-19 schematically illustrate various stages of manufacturing a semiconductor device according to embodiments of the present disclosure.

FIG. 20 is a flow chart of a method for manufacturing of a semiconductor device according to embodiments of the present disclosure.

FIGS. 21-23 and 23A-23B schematically illustrate various stages of manufacturing a semiconductor device according to embodiments of the present disclosure.

FIG. 24 is a flow chart of a method for manufacturing of a semiconductor device according to embodiments of the present disclosure.

FIGS. 25-26 schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of the present disclosure provide an etch back process which may be used in any process that needs bottom protection irrespective of the dimensions or the material of the bottom area to be protected. In some embodiments, a protective layer is formed using the etch back process over bottom materials/structures to be protected. In some embodiments, the bottom materials/structures may be STI and bottom spacers. The protective layer may be used to protect the STI and bottom spacers during the S/D loop, which includes all stations/stages that are used to form sources/drains regions, including patterning, etching, and epitaxy. The protective layer prevents STI loss and bottom spacer loss during the S/D loop, thus, avoiding structure damages, reducing leaks, and improving device performance. The protective layer formed by the etch back process according to the present disclosure can also slow down the etching of sidewall spacers during the etching back of the semiconductor stacks, so as to reduce the loss in height of sidewall spacers in S/D loop. The protective layer may also reduce the amount of residuals distributed on top surfaces during patterning, thus, reducing damages and improving process quality.

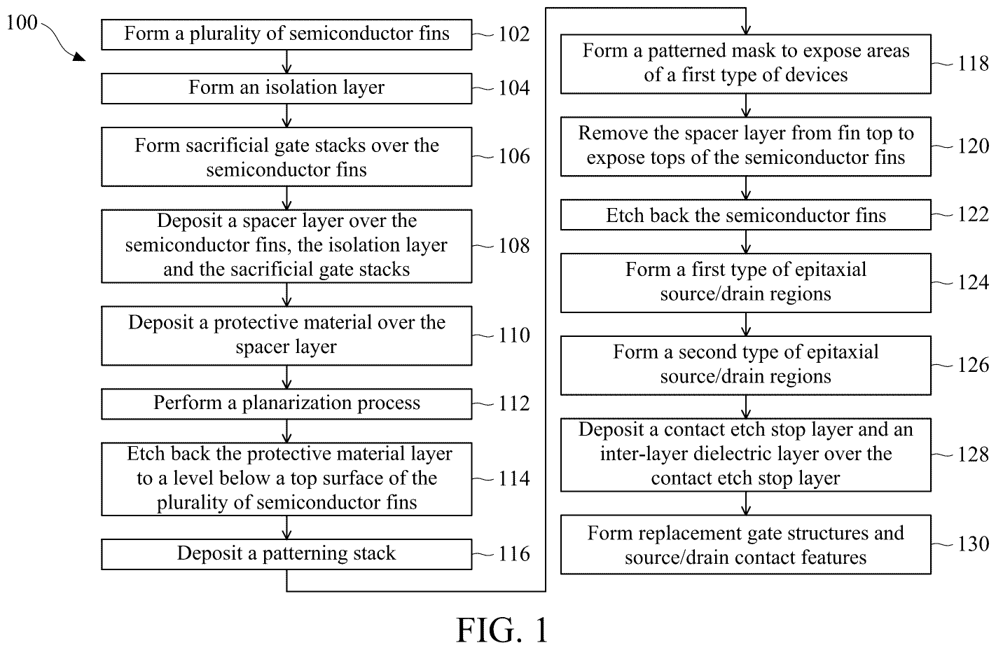

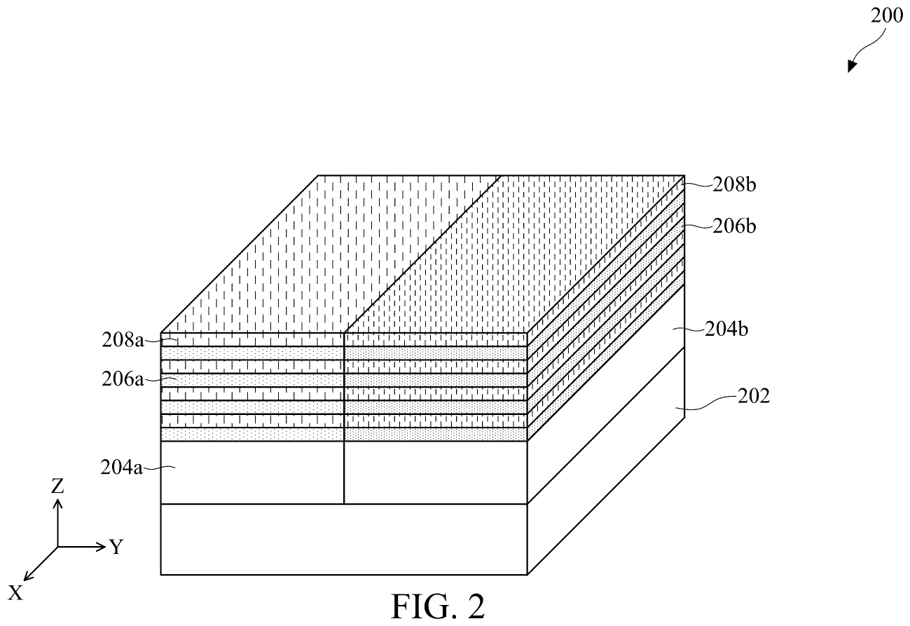

FIG. 1 is a flow chart of a method 100 for manufacturing of a semiconductor device 200 according to embodiments of the present disclosure. FIGS. 2-7, 7A-7B, 8, 8A-8B, 9-12, 12A-12G, 13-15, 15A-15E, 16, and 16A-E schematically illustrate various stages of manufacturing an exemplary semiconductor device 200 according to embodiments of the present disclosure. Particularly, the semiconductor device 200 may be manufactured according to the method 100 of FIG. 1.

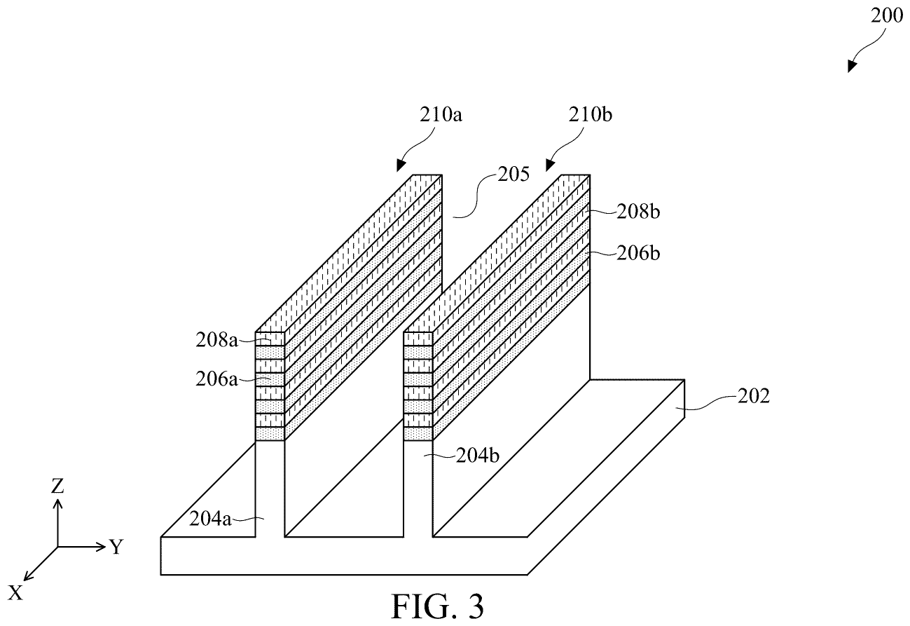

At operation 102 of the method 100, a plurality fin structures are formed on a substrate where a semiconductor device is to be formed. FIGS. 2 and 3 are schematic perspective view of the semiconductor device 200. As shown in FIG. 2, a substrate 202 is provided to form the semiconductor device 200 thereon. The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. In FIG. 2, the substrate 202 includes a p-doped region or p-well 204a and an n-doped region or n-well 204b. One or more n-type devices, such as nFETs, are to be formed over and/or within p-well 204a. One or more p-type devices, such as pFETs, are to be formed over and/or within n-well 204b. FIG. 2 shows that the p-well 204a is in a doped local region of a doped substrate, which is not limiting. In other embodiments, the p-well 204a and the n-well 204b may be separated by one or more insulation bodies, e.g., STI.

A semiconductor stack including alternating first semiconductor layers 206a and second semiconductor layers 208a is formed over the p-well 204a to facilitate formation of nanosheet channels in a multi-gate n-type device, such as nanosheet channel nFETs. The first semiconductor layers 206a and second semiconductor layers 208a have different compositions. In some embodiments, the two semiconductor layers 206a and 208a provide for different oxidation rates and/or different etch selectivity. In later fabrication stages, portions of the second semiconductor layers 208a form nanosheet channels in a multi-gate device. Four first semiconductor layers 206a and four second semiconductor layers 208a are alternately arranged as illustrated in FIG. 2 as an example. More or less semiconductor layers 206a and 208a may be included depending on the desired number of channels in the semiconductor device to be formed. In some embodiments, the number of semiconductor layers 206a and 208a is between 1 and 10.

In some embodiments, the first semiconductor layer 206a may include silicon germanium (SiGe). The first semiconductor layer 206a may be a SiGe layer including more than 25% Ge in molar ratio. For example, the first semiconductor layer 206a may be a SiGe layer including Ge in a molar ration in a range between 25% and 50%. The second semiconductor layer 208a may include silicon. In some embodiments, the second semiconductor layer 208a may be a Ge layer. The second semiconductor layer 208a may include n-type dopants, such as phosphorus (P), arsenic (As), etc.

Similarly, a semiconductor stack including alternating third semiconductor layers 206b and fourth semiconductor layers 208b is formed over the n-well 204b to facilitate formation of nanosheet channels in a multi-gate p-type device, such as nanosheet channel pFETs.

In some embodiments, the third semiconductor layer 206b may include silicon germanium (SiGe). The third semiconductor layer 206b may be a SiGe layer including more than 25% Ge in molar ratio. For example, the third semiconductor layer 206b may be a SiGe layer including Ge in a molar ration in a range between 25% and 50%. The fourth semiconductor layer 208b may include silicon, Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof. In some embodiments, the fourth semiconductor layer 208b may be a Ge layer. The fourth semiconductor layer 208b may include p-type dopants, boron etc.

The semiconductor layers 206a, 206b, 208a, 208b may be formed by a molecular beam epitaxy (MBE) process, a metalorganic chemical vapor deposition (MOCVD) process, and/or other suitable epitaxial growth processes. The semiconductor stacks over the n-well 204b and the p-well 204a may be formed separately using patterning technology.

Fin structures 210a, 210b (collectively 210) are then formed from etching the semiconductor stacks and a portion of the n-well 204b, the p-well 204a underneath respectively, as shown in FIG. 3. The fin structures 210a, 210b are substantially parallel and are separated by trenches 205. Even though, fin structures 210a, 210b for nanosheet FET devices are shown in the semiconductor device 200, embodiments of the present disclosure are also applicable to planar FETs, Fin-FETs, Horizontal Gate All Around (HGAA) FETs, Vertical Gate All Around (VGAA) FETs, and other suitable devices.

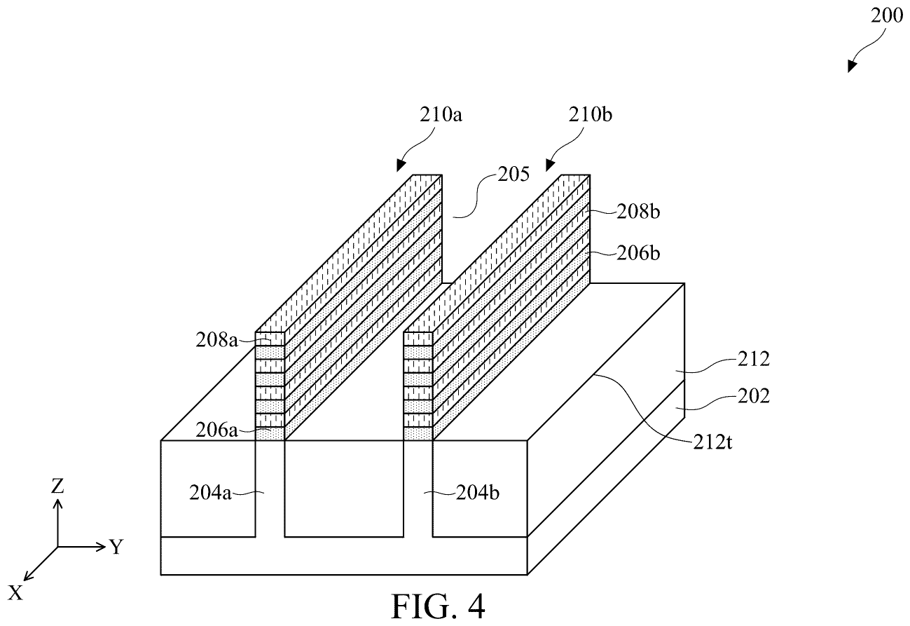

At operation 104, an isolation layer 212 are subsequently formed as shown in FIG. 4, which is a schematic view of the semiconductor device 200. The isolation layer 212 is filled in the trenches between the fin structures 210a, 210b and then etched back to below the semiconductor stacks of the fin structures 210a, 210b. The isolation layer 212 may be formed by a high-density plasma chemical vapor deposition (HDP-CVD), a flowable CVD (FCVD), or other suitable deposition process. In some embodiments, the isolation layer 212 may include silicon oxide, silicon nitride, silicon oxynitride, fluorine-doped silicate glass (FSG), a low-k dielectric, combinations thereof. In some embodiments, the isolation layer 212 is formed to cover the fin structures 210a, 210b by a suitable deposition process to fill the trenches 205 between the fin structures 210a, 210b, and then recess etched using a suitable anisotropic etching process to expose the active portions of the fin structures 210a, 210b. As shown in FIG. 4, after operation 104, the isolation layer 212 fills bottom portions of the trenches 205 between fin structures 210. Particularly, the stacks of semiconductor layers 206a, 206b, 208a, 208b extend above a top surface 212t of the isolation layer 212.

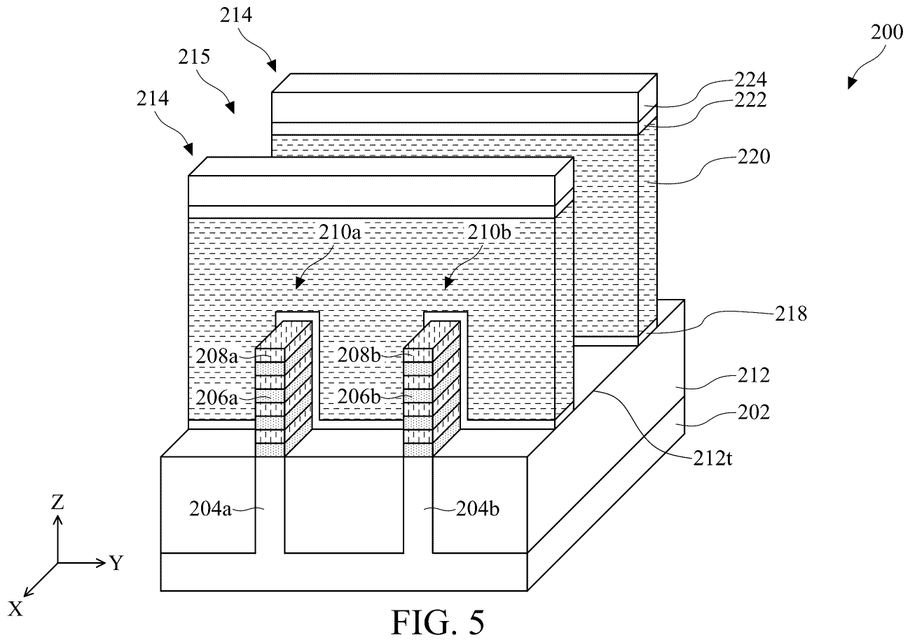

At operation 106, sacrificial gate structures 214 are formed over the isolation layer 212 and around the exposed portions of the fin structures 210a, 210b, as shown in FIG. 5, which is a schematic perspective view of the semiconductor device 200. The sacrificial gate structures 214 are formed over portions of the fin structures 210a, 210b which are to be channel regions. Trenches 215 are formed between neighboring sacrificial gate structures 214. The sacrificial gate structures 214 are substantially perpendicular to the fin structures 210. The trenches 215 are substantially perpendicular to the trenches 205 and cutting the trenches 205 into sections. The sacrificial gate structures 214 may include a sacrificial gate dielectric layer 218, a sacrificial gate electrode layer 220, a pad layer 222, and a mask layer 224.

The sacrificial gate dielectric layer 218 may be formed conformally over the fin structures 210a, 210b, and the isolation layer 212. In some embodiments, the sacrificial gate dielectric layer 218 may be deposited by a CVD process, a sub-atmospheric CVD (SACVD) process, a FCVD process, an ALD process, a PVD process, or other suitable process. The sacrificial gate dielectric layer 218 may include one or more layers of dielectric material, such as SiO₂, SiN, a high-k dielectric material, and/or other suitable dielectric material.

The sacrificial gate electrode layer 220 may be blanket deposited on the over the sacrificial gate dielectric layer 218. The sacrificial gate electrode layer 220 includes silicon such as polycrystalline silicon or amorphous silicon. The thickness of the sacrificial gate electrode layer is in a range between about 42 nm and about 200 nm. In some embodiments, the sacrificial gate electrode layer 220 is subjected to a planarization operation. The sacrificial gate electrode layer 220 may be deposited using CVD, including LPCVD and PECVD, PVD, ALD, or other suitable process.

Subsequently, the pad layer 222 and the mask layer 224 are formed over the sacrificial gate electrode layer 220. The pad layer 222 may include silicon nitride. The mask layer 224 may include silicon oxide. Next, a processing sequence including patterning and etching is performed on the mask layer 224, the pad layer 222, the sacrificial gate electrode layer 220 and the sacrificial gate dielectric layer 218 to form the sacrificial gate structures 214. Portions of the sacrificial gate electrode layer 220 and the sacrificial gate dielectric layer 218 are sequentially removed using patterns formed in the mask layer 224 to form the sacrificial gate structures 214. In some embodiments, the sacrificial gate electrode layer 220 is first etched using the sacrificial gate dielectric layer 218 as an etch stop layer. The sacrificial gate dielectric layer 218 is then electively removed from the fin structures 210 and from the isolation layer 212 to expose portion of the fin structures 210 and the top surface 212t of the isolation layer 212, as shown in FIG. 5. The removal of the sacrificial gate dielectric layer 218 relies on the etching selectivity between the isolation layer 212 and the sacrificial gate dielectric layer 218. However, high etching selectivity is hard to achieve when materials are similar. Thus, the isolation layer 212 may suffer some loss during removal of the sacrificial gate dielectric layer 218. Loss of the isolation layer 212 may cause various problems, such as current leakage caused by poor electrical isolation, collapse of hard mask structures, or undesirable openings under sidewall spacers. Embodiments of the present disclosure provide a protective layer to protect the isolation layer 212 and to compensate loss of isolation layer 212 during fabrication of the sacrificial gate structures 214.

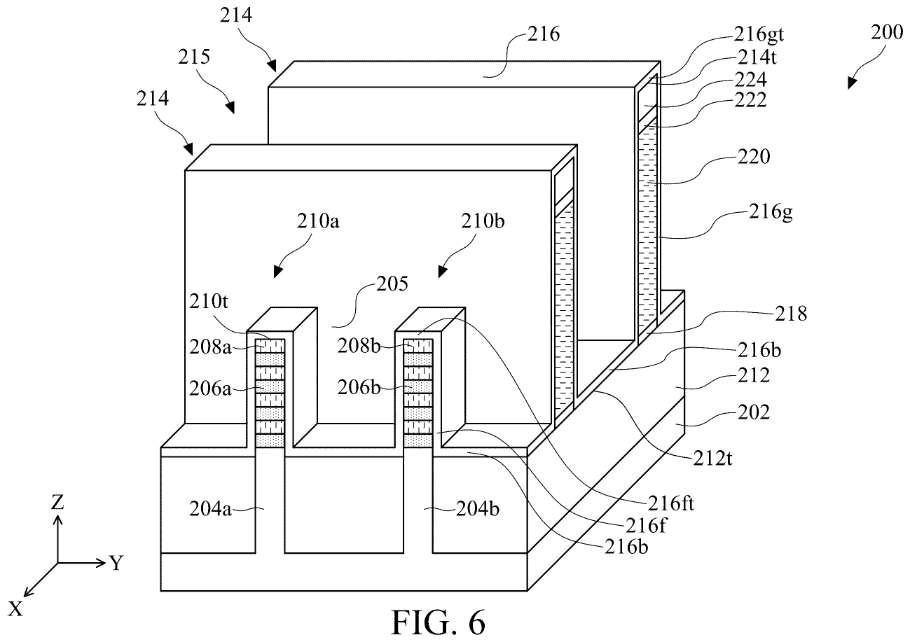

At operation 108, a spacer layer 216 is formed over the semiconductor device 200, as shown in FIG. 6, which is a schematic perspective view of the semiconductor device 200. After the sacrificial gate structures 214 are formed, the spacer layer 216 may be deposited over the semiconductor device 200 by a blanket deposition of one or more insulating material. Even though only one layer is shown in FIG. 6, the spacer layer 216 may include two or more layers of dielectric materials. In some embodiments, the spacer layer 216 may include one or more insulation material. The spacer layer 216 may include a silicon nitride-based material, such as SiN, SiON, SiOCN or SiCN and combinations thereof.

As shown in FIG. 6, the spacer layer 216 covers the sacrificial gate structures 214, the fin structures 210a, 210b, and the isolation layer 212. For clarity of description, portions of the spacer layer 216 formed on sidewalls of the sacrificial gate structures 214 are referred to as gate sidewall spacers 216g, portions of the spacer layer 216 formed on sidewalls of the fin structures 210a, 210b are referred to as fin sidewall spacers 216f, portions of the spacer layer formed on the isolation layer 212 are referred to as bottom spacers 216b, portions of the portions of the spacer layer 216 formed on top surfaces 214t of the sacrificial gate structures 214 are referred gate top spacers 216gt, and portions of the portions of the spacer layer 216 formed on top surfaces 210t of the fin structures 210a, 210b are referred fin top spacers 216ft.

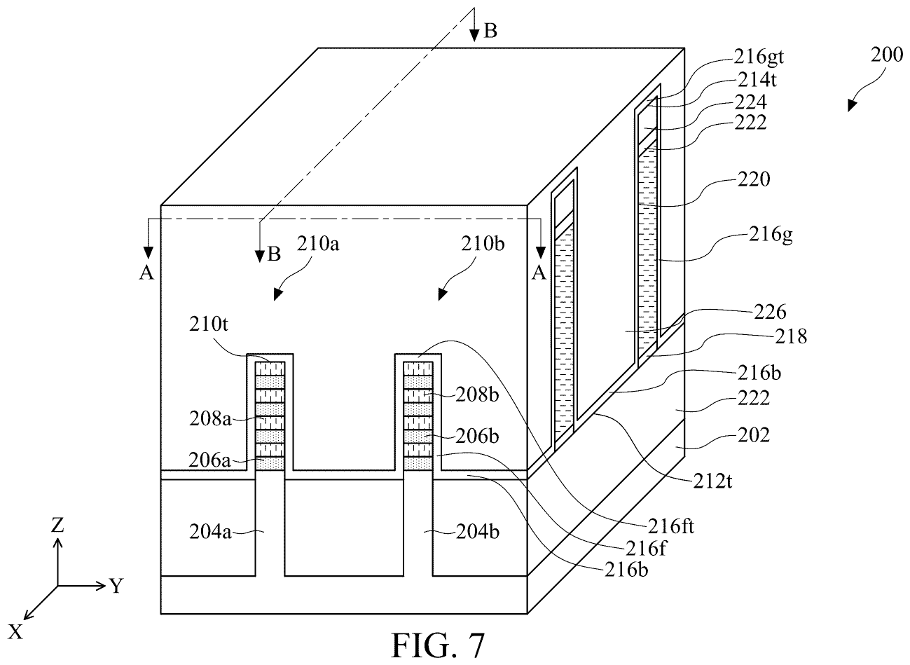

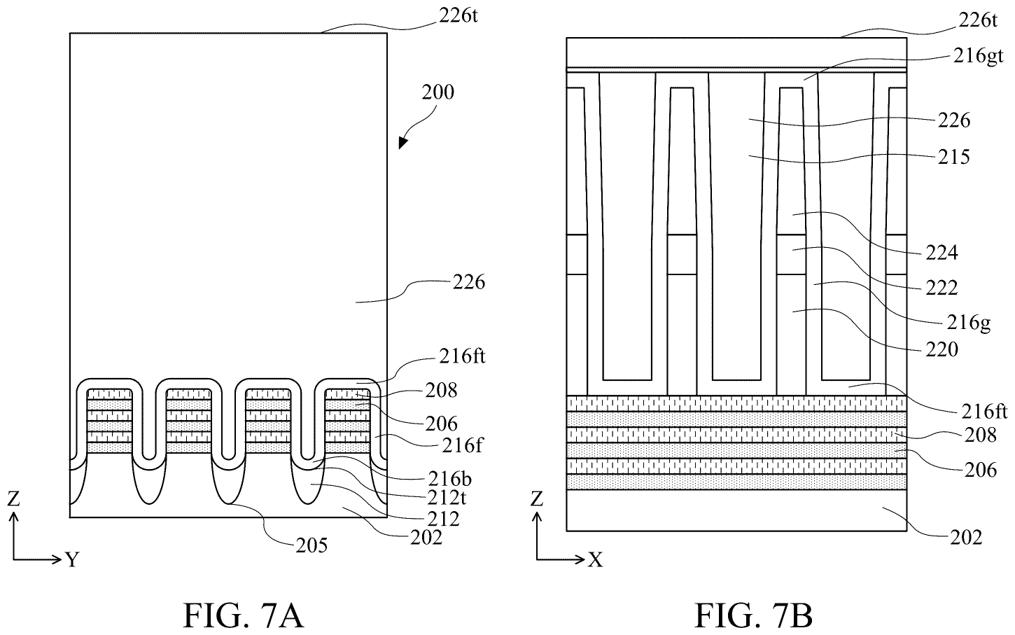

In operation 110, a protective layer 226 is deposited over the semiconductor device 200, as shown in FIG. 7, which is a schematic perspective view of the semiconductor device 200. After operation, the fin structures 210 and the sacrificial gate structures 214 are immersed in the protective layer 226. The protective layer 226 may be selected from materials having etch selectivity with the materials in the spacer layer 216 and the fin structures 210 so that the protective layer 226 may be used to protect underlying structures in the subsequent removal of the spacer layer 216 and the fin structures 210.

In some embodiments, the protective layer 226 may include one or more dielectric material. The protective layer 226 may include silicon oxide, silicon nitride, silicon oxynitride, fluorine-doped silicate glass (FSG), a low-k dielectric, combinations thereof. The protective layer 226 may be formed by a suitable deposition process, for example, by FCVD, HDP-CVD, PVD, ALD, CVD. In some embodiments, the protective layer 226 may include silicon oxide deposited by FCVD.

The protective layer 226 may include other materials, such as metal or metal oxide. In some embodiments, the protective layer 226 may include aluminum, copper, titanium, tantalum, tungsten, cobalt, molybdenum, ruthenium, an alloy thereof, or a combination thereof, which is formed by CVD, ALD, electro-plating, or other suitable method. In other embodiments, the protective layer 226 may include one or more metal oxides, such as HfO₂, HfSiO, HfSiON, HfTaO, HfTiO, HfZrO, zirconium oxide, aluminum oxide, titanium oxide, lanthanum oxide, yttrium oxide, hafnium dioxide-alumina (HfO₂—Al₂O₃) alloy, and/or combinations thereof, which may be formed by CVD, ALD or any suitable method.

In some embodiments, an optional anneal process may be performed after deposition of the protective layer 226. An anneal process may enhance the protective layer 226, for example to make the protective layer 226 denser to provide improved protection. In some embodiments, the protective layer 226 may be annealed at a temperature in a range between about 200° C. and about 1200° C. In some embodiments, the anneal process may be performed for a time period between about 5 seconds and about 5 hours. In some embodiments, the anneal process may not be needed as the protective layer 226 already strong enough or it need to be weak enough for remove by following process.

In some embodiments, the sacrificial gate electrode layer 220 and the spacer layer 216 may also be enhanced by anneal process. In some embodiments, when the protective layer 226 includes silicon oxide or metal oxide, oxygen may diffuse into the spacer layer 216 making the spacer layer 216 harder. The protective layer 226 with different composition may lead to different results in the spacer layer 216. For example, when the protective layer 226 includes a metal or a metal oxide, the metal atoms may diffuse into the neighboring materials, such as the spacer layer 216. Metal atoms diffused into the spacer layer 216 and/or the sacrificial gate electrode layer 220 may make the spacer layer 216 and/or the sacrificial gate electrode layer 220 stronger. For example, the spacer layer 216 may be enhanced by metal atoms and obtain increased etching resistance.

As shown in FIG. 7, the protective layer 226 is deposited to cover the sacrificial gate structures 214. The protective layer 226 fills the trenches 205 between the fin structures 210 and the trenches 215.

FIGS. 7A and 7B are schematic transmission electron microscopy images showing actual shapes of the semiconductor device 200. FIG. 7A is a schematic y-cut view, or a cross sectional view along the A-A line in FIG. 7. FIG. 7B is a schematic x-cut view, or a cross sectional view along the B-B line in FIG. 7. As shown in FIGS. 7A and 7B, the top surface 212t of the isolation layer 212 may be curved and dipped below the semiconductor layers of the fin structures 210. The protective layer 226 cover the bottom spacer 216b.

In operation 112, an optional planarization process, such as CMP, may be performed to obtain a flat top surface 226t on the protective layer 226, as shown in FIG. 7. A flat top surface 226t improves process uniformity for the subsequent etch back process. In some embodiments, the CMP process may be used to remove a bulk portion of the protective layer 226 over the gate top spacer 216gt, thus, to improve process efficiency. In some embodiment, the planarization process may be omitted when the top surface of the protective layer 226 is substantially flat after deposition.

In some embodiments, the CMP process may be performed to the level where the mask layer 224 in the sacrificial gate structures 214 is exposed. As a result, the mask layer 224 acquires a flat or square profile in the cross section along the x-z plane. The square profile of the sacrificial gate structures 214 may reduce ion reflection during the subsequent etching process and obtain improved etch profiles.

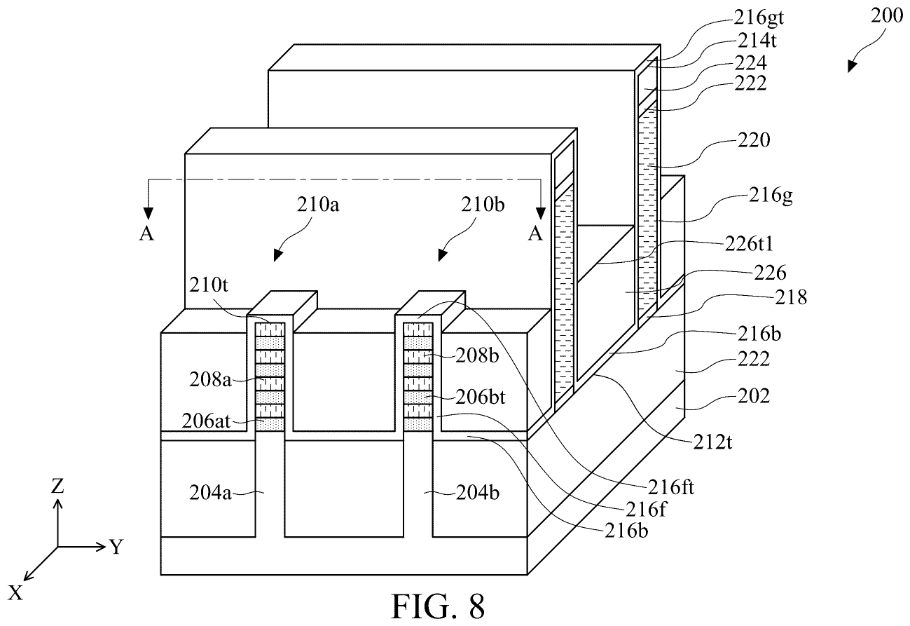

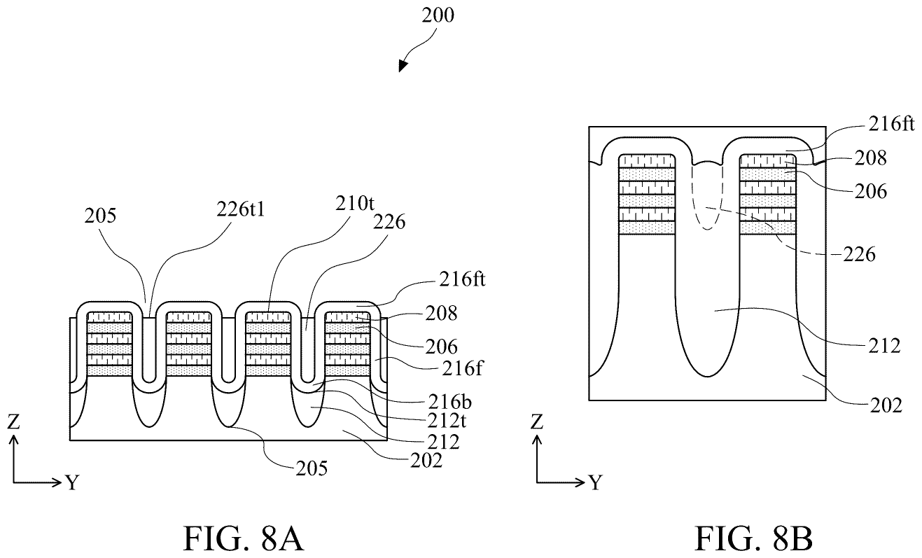

In operation 114, an etch back process is performed to the protective layer 226 so that a top surface 226t1 is below the fin top spacer 226ft, as shown in FIG. 8, which is a schematic perspective view of the semiconductor device 200. The etch back process may be an isotropic etching process such a dry chemical etching or wet etching, or an anisotropic etching process such as dry plasma etching. In some embodiments, a desired thickness of the remaining protective layer 226 may be obtained by adjusting etching time.

As shown in FIG. 8, after etching back of the protective layer 226, the trenches 205 between the fin structures 210 remain substantially filled by the protective layer 226. In some embodiments, the top surface 226t1 is below the top surface 210t of the fin structure 210 so that the fin top spacers 216ft extend above the protective layer 226. In some embodiments, the top surface 226t1 is above a certain level to prevent holding any photoresist residual in the trenches 205 between fin structures 210 in the subsequent patterning process. In some embodiments, the top surface 226t1 may be at a level above the top-most semiconductor layer 206at or 206bt.

FIG. 8A is a schematic y-cut view of the semiconductor device 200, or a cross sectional view along the A-A line in FIG. 8. As shown in FIG. 8A, the trenches 205 between the fin structures 210 remains substantially filled with the protective layer 226. The bottom spacer 216b and the isolation layer 212 are covered by the protective layer 226. FIG. 8B is a schematic cross-sectional image of a semiconductor device fabricated according to the present disclosure. The protective layer 226 is filled above the isolation layer 212.

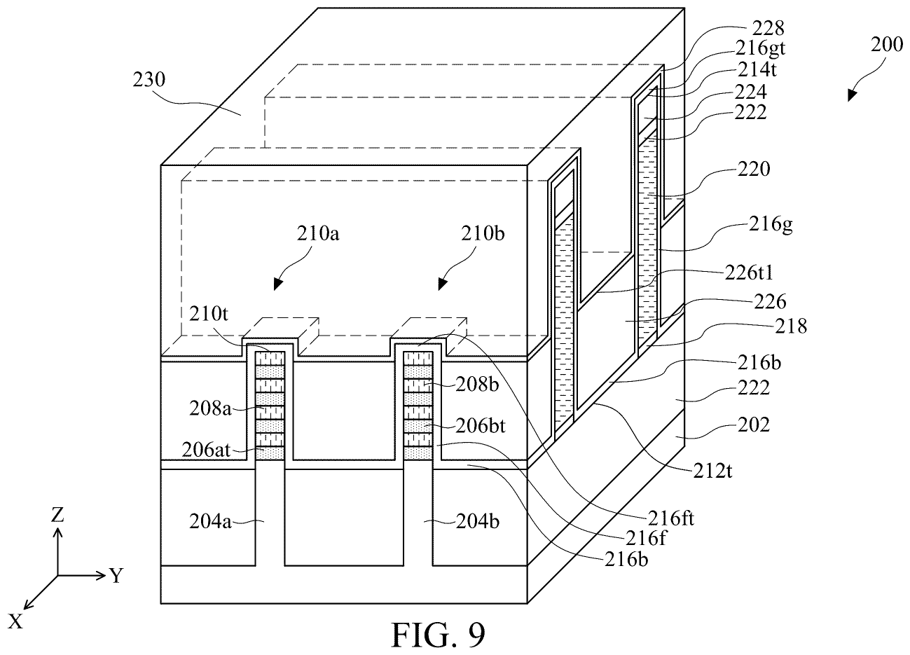

In operation 116, a pattern stack is formed over the semiconductor device 200, as shown in FIG. 9, which is a schematic perspective view of the semiconductor device 200. In some embodiments, the pattern stack may include a hard mask layer 228 and a photoresist layer 230.

The hard mask layer 228 is deposited over exposed surfaces of the semiconductor device 200, such as the top surface 226t1 of the protective layer 226, and the spacer layer 216, such as the fin top spacers 216ft, the gate sidewall spacers 216g, and the gate top spacers 216gt. In some embodiments, the hard mask layer 228 may include an aluminum oxide (AlOₓ) layer. Other suitable materials capable of withstanding the processing conditions of epitaxial source/drain formation.

The photoresist layer 230 is coated over the hard mask layer 228. The photoresist layer 230 may be a tri-layer photoresist. The tri-layer photoresist 230 may include an underlayer deposited on the hard mask layer 228, a middle layer deposited over the underlayer, and a top layer deposited over the middle layer.

The underlayer may be an organic material, such as a plurality of monomers or polymers that are not cross-linked. Generally, the underlayer layer may contain a material that is patternable and/or have a composition tuned to provide anti-reflection properties. Exemplary materials for the underlayer include a carbon backbone polymer. In some embodiments, the underlayer may be omitted. In some embodiments, the underlayer may be formed by a spin coating process. In other embodiments, the underlayer may be formed by another suitable deposition process.

The middle layer may have a composition that provides anti-reflective properties and/or hard mask properties for the lithography process. In some embodiments, the middle layer may include a silicon-containing inorganic polymer. In other embodiments, the middle layer may include silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials. The middle layer may be thermally baked for cross-linking, thus without further requiring a solvent.

The top layer may be a photoresist (PR) layer. The PR layer may be a photosensitive layer operable to be patterned by a radiation as known in the art. The chemical properties of the photoresist regions struck by incident radiation change in a manner that depends on the type of photoresist used. The PR layer may include a carbon backbone polymer. The PR layer may include other suitable components such as a solvent and/or photo acid generators. For example, in a further embodiment, the PR layer is a chemical amplified (CA) resist known in the art. In one embodiment, the photoresist layer includes a photo-acid generator (PAG) distributed in the photoresist layer. When absorbing photo energy from an exposure process, the PAG forms a small amount of acid. The resist may include a polymer material that varies its solubility to a developer when the polymer is reacted with this generated acid. The CA resist may be a positive tone resist. Examples of suitable PAGs include salts of sulfonium cations with sulfonates, salts of iodonium cations with sulfonates, sulfonyldiazomethane compounds, N-sulfonyloxyimide PAGs, benzoinsulfonate PAGs, pyrogallol trisulfonate PAGs, nitrobenzyl sulfonate PAGs, sulfone PAGs, glyoxime derivatives, triphenylsulfonium nonaflate, and/or other suitable PAGs now known or later developed. One or more of these PAGs may generate an acid that interacts with the base generated by the PBG of the middle layer after exposure and/or hard baking, as described herein.

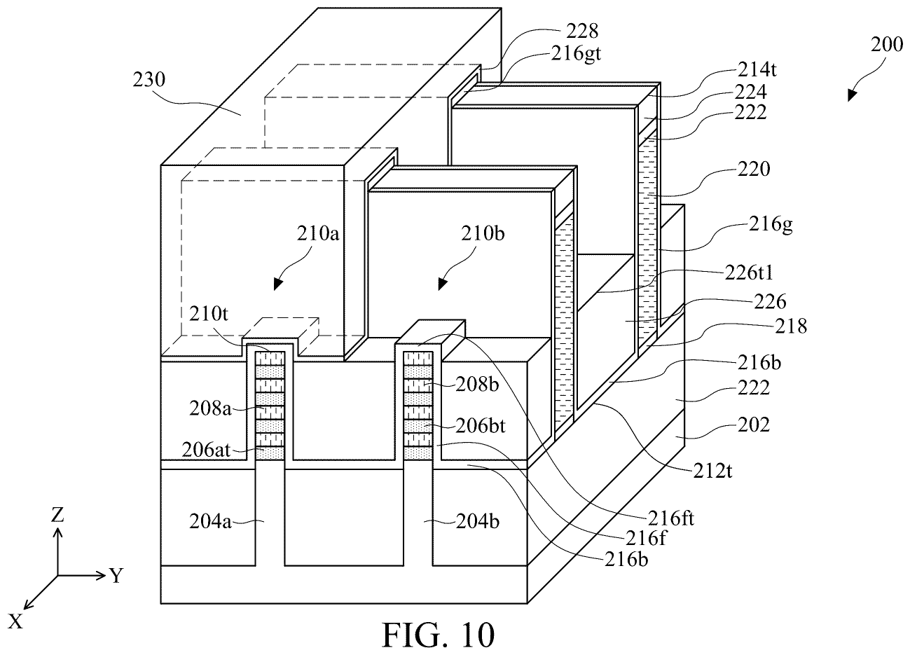

In operation 118, a photolithography process is performed to pattern the hard mask layer 228 to expose process areas, as shown in FIG. 10, which is a schematic perspective view of the semiconductor device 200. In some embodiments, the hard mask layer 228 is patterned to expose areas where a first type of devices. For example, areas of the p-well 204a, where P-type devices are to be formed, are exposed for processing. Alternatively, the n-well 204b areas may be exposed as discussed other examples. In other embodiments, both p-well areas 204a and n-well areas 204b are exposed while other areas of the substrate 202 are covered.

After the photolithography process, an ashing process is performed to remove the tri-layer photoresist 230, and an etch process is performed to remove the portion of the hard mask layer 228. In some embodiments, the etch process to remove the portion of the hard mask layer 228 includes a wet etch process, a dry etch process, or a combination thereof. The photoresist layer 230 may be removed by a suitable process, such as a wet strip process, prior to forming epitaxial source/drain regions.

Because the protective layer 226 substantially fills the trenches 205 adjacent the fin structures 210, residuals of the photoresist layer 230 and the hard mask layer 228 may remain after the patterning process.

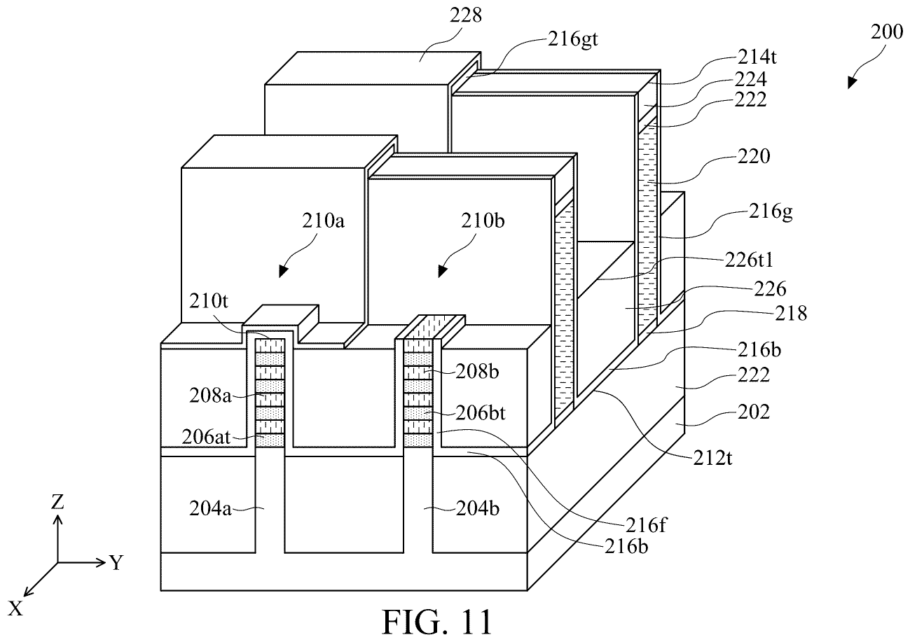

In operation 120, an etch process is performed to remove the fin top spacers 216ft to expose the top surface 210t of the fin structures 210, as shown in FIG. 11, which is a schematic perspective view of the semiconductor device 200. In some embodiments, the fin top spacers 216ft may be removed by an anisotropic etch to remove the spacer layer 216 from horizontal surfaces. The gate top spacers 216gt are also removed during this operation.

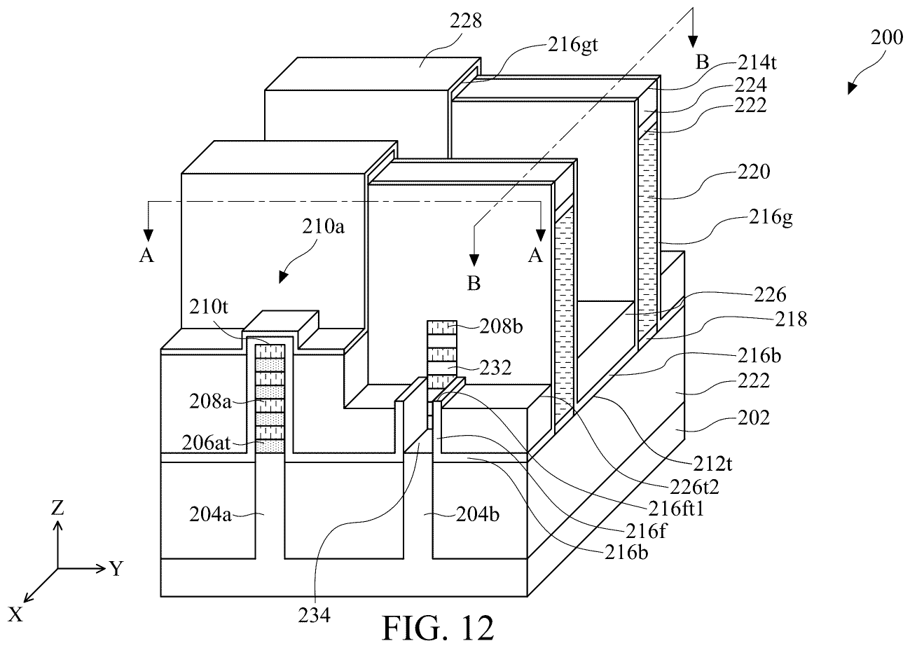

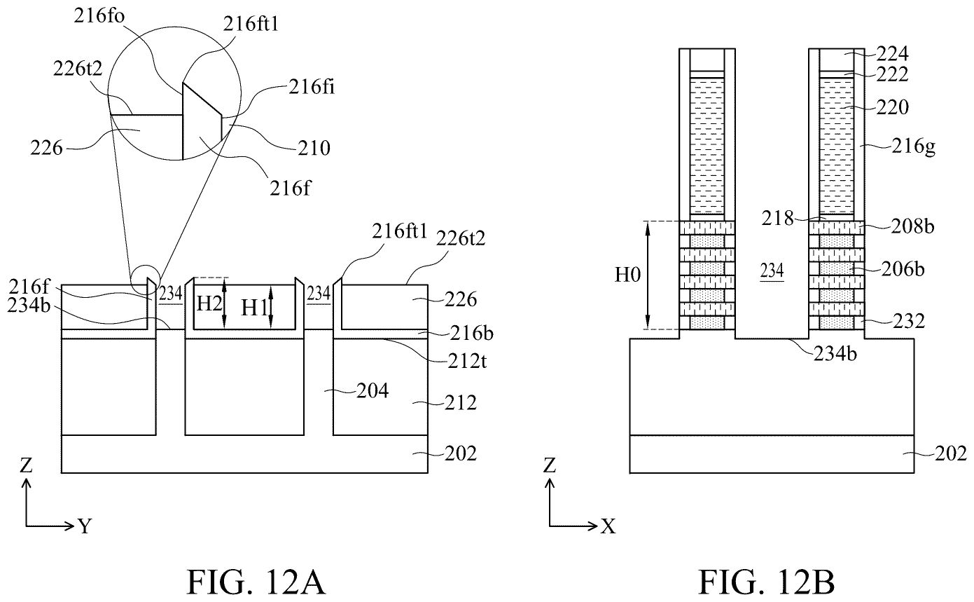

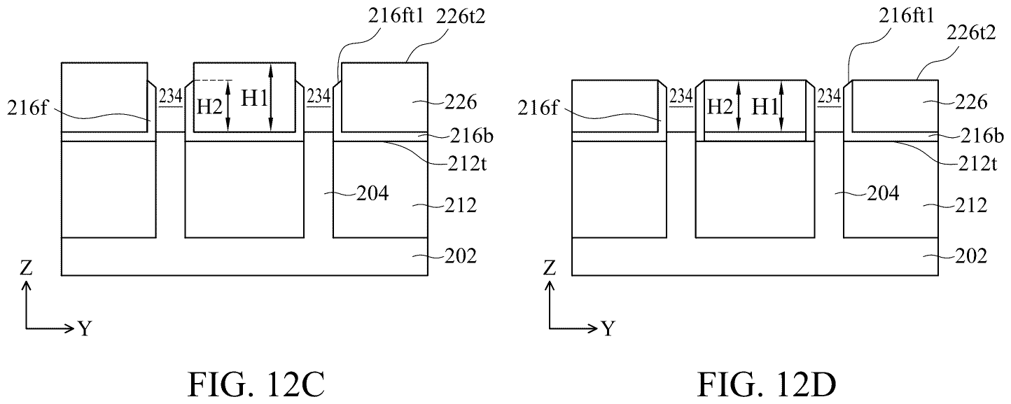

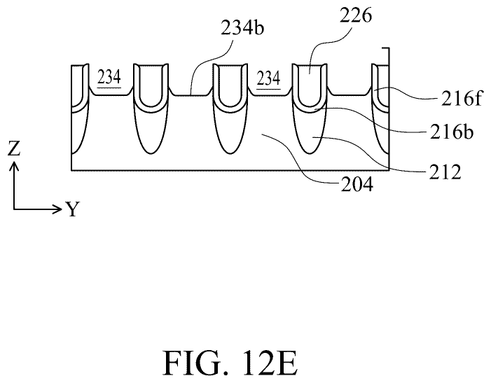

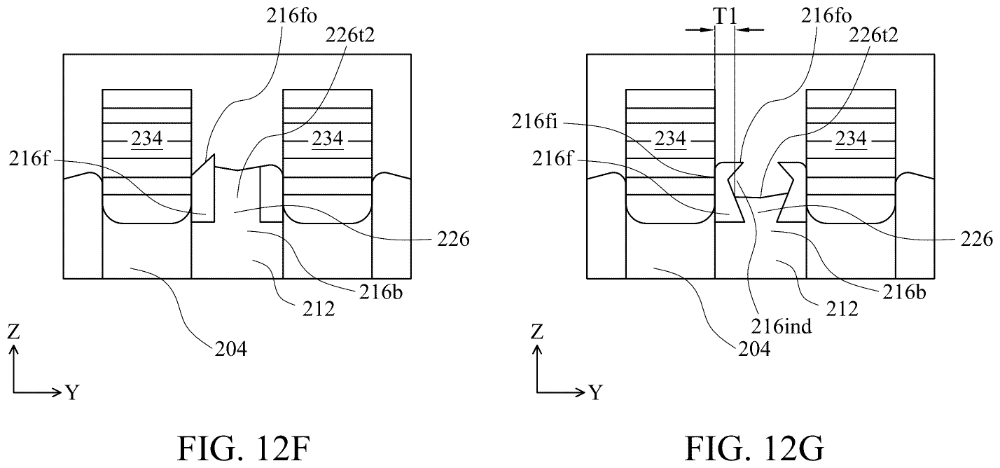

In operation 122, the fin structures 210 not covered by the sacrificial gate structures 214 or the hard mask layer 224 are etched to expose well portions of each fin structures 210 to form source/drain recess 234, as shown in FIGS. 12, 12A-12B. FIG. 12 is a schematic perspective view of the semiconductor device 200. FIGS. 12A and 12B are schematic transmission electron microscopy images showing actual shapes of the semiconductor device 200. FIG. 12A is a schematic y-cut view, or a cross sectional view along the A-A line in FIG. 12. FIG. 12B is a schematic x-cut view, or a cross sectional view along the B-B line in FIG. 12.

In some embodiments, suitable dry etching and/or wet etching may be used to etch back the semiconductor layers 206, 208, together or separately. A portion of the fin sidewall spacers 216f may remain after the fin structures 210 are recessed. A height of the remaining fin sidewall spacers 216f may be used to control the shape of the subsequently formed epitaxial source/drain regions.

After recess etch of the fin structures 210, inner spacers 232 are formed through the source/drain recesses 234. To form the inner spacers 232, the semiconductor layers 206 under the gate sidewall spacers 216g are selectively etched from the semiconductor layers 208 along the horizontal direction, or x-direction, to form spacer cavities. In some embodiments, the semiconductor layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. After forming the spacer cavities, the inner spacers 232 are formed in the spacer cavities by conformally deposit and then partially remove an insulating layer. The insulating layer can be formed by ALD or any other suitable method. The subsequent etch process removes most of the insulating layer except inside the cavities, resulting in the inner spacers 232.

During the recess etch of the fin structures 210, portions of the protective layer 226 and portions of the fin sidewall spacers 216fs are also etched away. However, because the isolation layer 212 and the bottom spacers 216b are covered by the protective layer 226, therefore, incurred no loss at all. Similarly, the protective layer 226 also protects the isolation layer 212 and the bottom spacers 216b during the etch process for forming the inner spacers 232.

After the operation 122, a portion of the fin sidewall spacers 216f and a portion of the protective layer 226 remain on the top surface 212t of the isolation layer 212. As shown in FIGS. 12, 12A and 12B, after etch back of the fin structures 210, the protective layer 226 recesses to a top surface 226t2 and the protective layer 226 has a height H1, which is defined by a distance along the z-direction between the top surface 226t2 and a top surface of the bottom spacer 216b. After etch back of the fin structures 210, the fin sidewall spacers 216f recesses to a top surface 216ft1 and has a height H2, which is defined by a distance along the z-direction between the top surface 216ft1 and the top surface of the bottom spacer 216b. The heights H1 and H2 may be controlled according to the process design, for example, to achieve the certain shape and/or volume the source/drain regions to be formed. In some embodiments, the height H1 of the protective layer 226 may be in a range between about 0 nm and about 120 nm. In some embodiments, the protective layer 226 is substantially removed from the bottom spacer 216ft1 resulting in the height H1 is zero. The height H2 of the fin sidewall spacers 216f may be in a range between about −20 nm and about 125 nm. A negative height H2 indicates that the sidewall spacers 216f is etched below a top surface of the bottom spacer 216ft1.

The semiconductor stack 206/208 of the fin structure 210 may have a height H0 along the z-direction, as illustrated in FIG. 12B. In some embodiments, the height H1 and the height H2 are selected to be relative to the height H0 of the semiconductor stack of the fin structures 210. In some embodiments, the height H1 may be in designed according relative to the height H0 of the semiconductor stack of the fin structures 210. In some embodiments, a ratio of the height H1 over the height H0 is in a range between about 0 and about 1.2. In some embodiments, the protective layer 226 is substantially removed from the bottom spacer 216ft1 resulting in the ratio H1 over H2 is zero. In some embodiments, a ratio of the height H2 over the height H0 is in a range between about −0.2 and about 1.0. A negative ratio of H2 over H0 indicates that the sidewall spacers 216f is etched below a top surface of the bottom spacer 216ft1.

The relative height of the fin sidewall spacers 216f and the protective layer 226 may also be selected according to process design. In some embodiments, the fin sidewall spacers 216f are higher than the protective layer 226, as shown in FIG. 12A. FIGS. 12C and 12D are schematic cross-sectional views of the semiconductor device 200 with the fin sidewall spacers 216f lower than the protective layer 226 and the fin sidewall spacers 216f at substantially the same level as the protective layer 226 respectively. The different relative heights may be achieved by adjusting etching recipe during the etch back process.

Using the protective layer 226 during the etch back process in the operation 122 provide various advantages. As discussed above, with the physical coverage of the protective layer 226, the STI or isolation layer 212 and the bottom spacers 216b incur zero loss during the process, thus, eliminating any leakage or structure damages caused by STI loss.

Furthermore, using the protective layer 226 also eliminates process loading in STI loss and bottom spacer remains. The term “loading” refers to non-uniformity in a process, such as etching, between different locations on a wafer such as between center and edge, or among different pattern regions, such as between at regions with high pattern density and regions with low pattern density. When the protective layer 226 is not used, etching depths are different at different locations and/or different pattern regions, which is referred to as loading. Without the protective layer 226, both the isolation layer 212 and the bottom spacers 216b suffer loss during etch back of the fin structures 210, and the amount of loss is not uniform due to loading. With the protective layer 226 according to the present disclosure, there is no loss of the isolation layer 212 and the bottom spacers 216b, thus, also free of loading.

The protective layer 226 also enables a greater height in the fin sidewall spacers 216f because the combination of the spacer layer 216 and the protective layer 226 have better resistance against etching, thereby leading to higher fin sidewall spacers 216f.

The protective layer 226 allows additional flexibility in selecting etching recipes for recess etching the fin structures 210. For example, etching recipes with lower etching selectivity between the semiconductor layers 206/208 and the spacer layer 216/the protective layer 226 are available. In some embodiments, the etching recipe may be adjusted to make etch profiles of the fin structure 210 more squared, for example using a higher bias voltage during etching. As show in FIGS. 12A and 12B, a bottom profile 234b of the source/drain recess 234 is substantially squared. FIG. 12E is a schematic image of the semiconductor device 200. As shown in FIG. 12E, after the recess etch, the bottom profile 234b is substantially squared having a substantially planar section. In some embodiments, the bottom profile 234b may become more squared because of the flat profile of the sacrificial gate structures 214 from the CMP process in the operation 112.

In some embodiments, the shape of an individual fin sidewall spacer 216f asymmetric. For example, as shown in FIG. 12A, each fin sidewall spacer 216f may have an inner surface 216fi facing the fin structure 210 and an outer surface 216fo facing the protective layer 226. During recess etch of the fin structures 210, the etch chemistry is selected to have a higher etching rate to the fin structures 210 and a slower etching rate to the protective layer 226. The different etching rates adjacent the inner surface 210fi and the outer surface 210fo may result in different profiles on two sides of the fin sidewall spacer 216f. For example, as shown in the enlarged region in FIG. 12A, near a top portion of the fin sidewall spacer 216f, the fin sidewall spacer 216f may have a more square or sharp shape along the outer surface 216fo and a rounded corner along the inner surface 216fi. FIG. 12F is a schematic image of the semiconductor device 200 with an asymmetrically shaped the fin sidewall spacer 216f.

In some embodiments, the fin sidewall spacer 216f may have a rough shape due to the height difference between the fin sidewall spacer 216f and the protective layer 226. In some embodiments, when the protective layer 226 is etched faster than sidewall spacer than the fin sidewall spacers 216f, the fin sidewall spacer 216f may have a non-uniform thickness T1 along the y-direction, as shown in FIG. 12G, which is a schematic image of the semiconductor device 200 with an asymmetrically shaped the fin sidewall spacer 216f. As shown in FIG. 12G, an upper portion of the fin sidewall spacer 216f, which is exposed, has a larger thickness T1 than a lower portion of the fin sidewall spacer 216f, which is covered by the protective layer 226. In some embodiments, the outer surface 216fo of the upper portion of the fin sidewall spacer 216f may have a rough surface/shape. In some embodiments, an indention 216ind may be formed on the outer surface 216fo at the upper portion of the fin sidewall spacer 216f. The indention 216ind may be caused by ion reflection during etching process.

Because of the protective layer 226, less residuals of the photoresist layer 230 are leftover, which also enables higher flexibility in selection or adjustment of the etch recipes. In some embodiments, the etch recipe may be adjusted to reduce loading in profiles of the source/drain recesses 234, for example, reduce loading cross patterns, intra cells, between center-edge, and/or cross wafers. In some embodiments, the recess etch recipe may be adjusted to have less roughness in the etch profile in x-cut, y-cut, and plane cut. In some embodiments, the recess etch recipe may be adjusted to obtain vertical and bottom square etch profile in x-cut and y-cut. Additionally, the protective layer 226 are used to protect bottom features during this etching process without any overlay alignment issues.

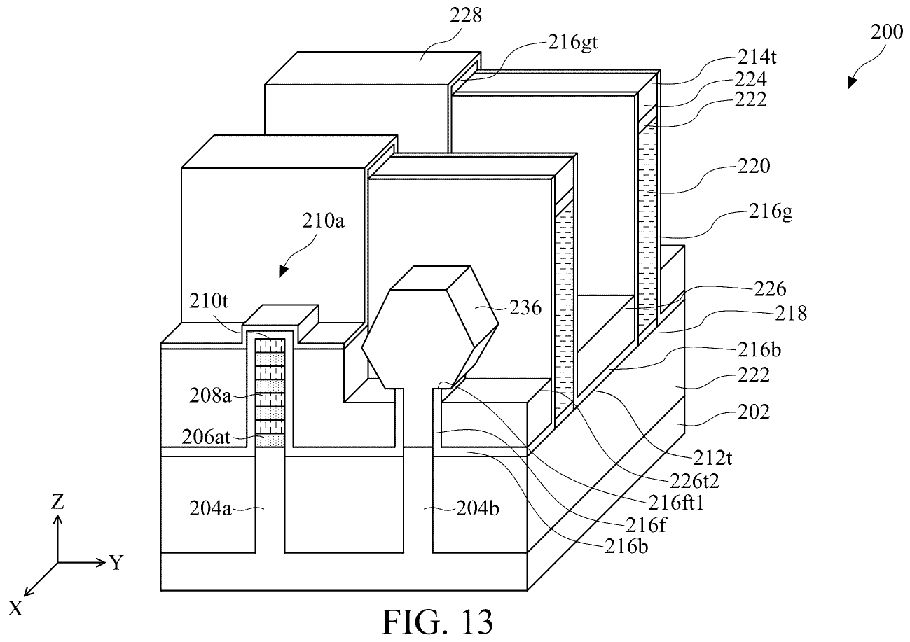

At operation 124, epitaxial source/drain regions of a first type of devices are formed, as shown in FIG. 13, which is a schematic perspective view of the semiconductor device 200. The first type of devices may be N-type devices or P-type devices. As shown in FIG. 13, epitaxial source/drain regions 236 for N-type devices are formed from exposed surfaces of the fin structure 210b.

The epitaxial source/drain regions 236 for n-type devices may include one or more layers of Si, SiP, SiC and SiCP. The epitaxial source/drain regions 236 also include N-type dopants, such as phosphorus (P), arsenic (As), etc. In some embodiments, the epitaxial source/drain regions 236 may be a Si layer includes phosphorus (P) dopants. The epitaxial source/drain regions 236 shown in FIG. 8 has an oval shape. However, the epitaxial source/drain regions 236 may be other shapes according to the design. The epitaxial source/drain regions 236 may be formed by any suitable method, such as by CVD, CVD epitaxy, molecular beam epitaxy (MBE), or any suitable deposition technique.

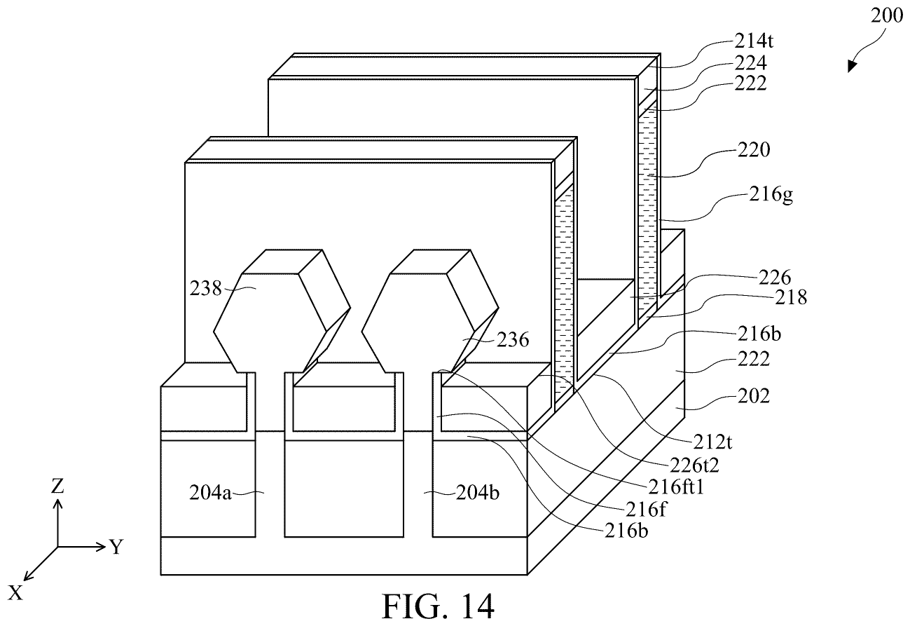

At operation 126, epitaxial source/drain regions 238 for the second type of devices are formed, as shown in FIG. 14, which is a schematic perspective view of the semiconductor device 200. As discussed above, the first type of devices are N-type devices and the second type of devices are P-type devices. Alternatively, the first type of devices are P-type devices and the second type of devices are N-type devices.

In some embodiments, after formation of the epitaxial source/drain regions 236, the hard mask layer 228 may be removed. The epitaxial source/drain regions 236 are then covered by a source/drain mask layer (not shown), which protects the epitaxial source/drain regions 236 during formation of the epitaxial source/drain regions 238. In some embodiment, the source/drain mask layer may be formed by a suitable photolithography process after removal of the hard mask layer 228. In other embodiments, the source/drain mask may be a self-aligned mask form before removal of the hard mask layer 228. Operations 114, 116, 118, 120, and 122 may be repeated to form a pattern to expose areas of n-wells 204a and recess etch the fin structures 210a to form source/drain recesses. The epitaxial source/drain regions 238 may be formed by any suitable method, such as by CVD, CVD epitaxy, molecular beam epitaxy (MBE), or any suitable deposition technique. In some embodiments, the epitaxial source/drain regions 238. The epitaxial source/drain regions 238 for the p-type devices may include one or more layers of Si, SiGe, Ge with p-type dopants, such as boron (B), for a p-type device, such as pFET. In some embodiments, the epitaxial source/drain regions 238 may be SiGe material including boron as dopant. The source/drain mask may be removed from the epitaxial source/drain regions 236 after formation of the epitaxial source/drain regions 238.

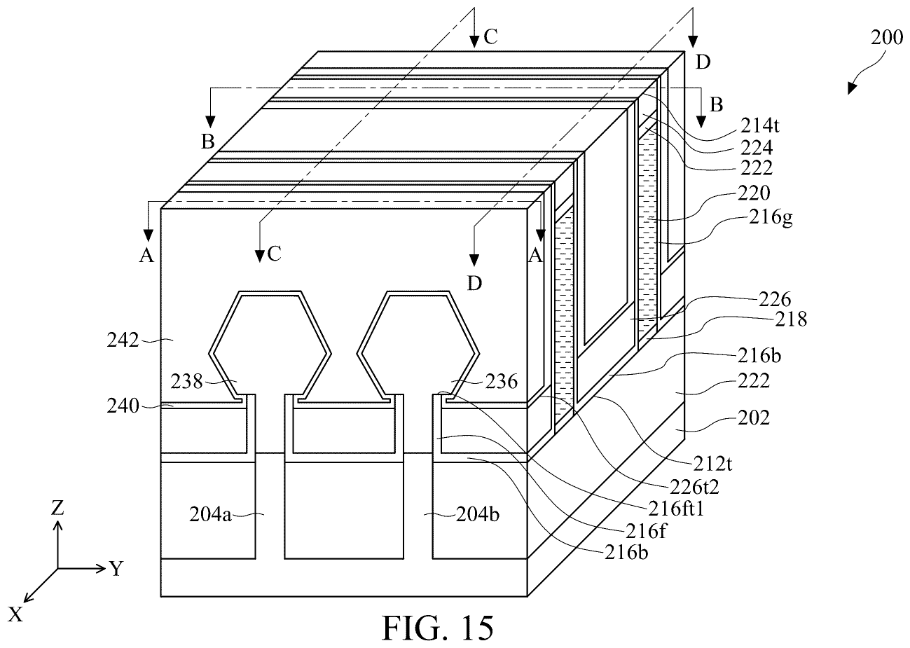

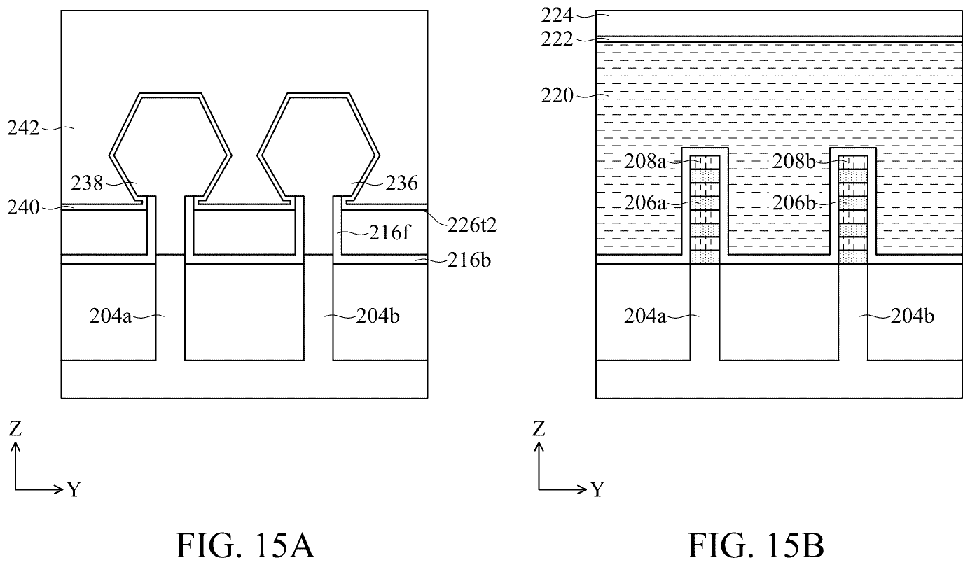

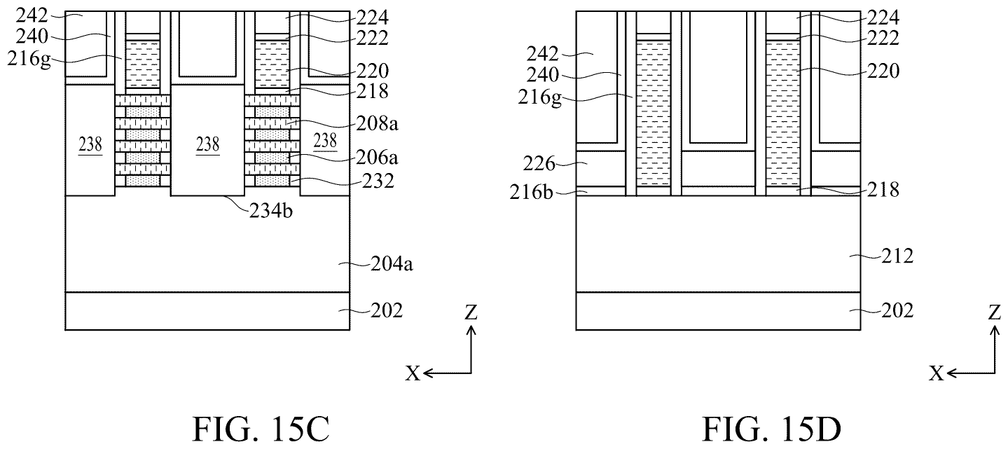

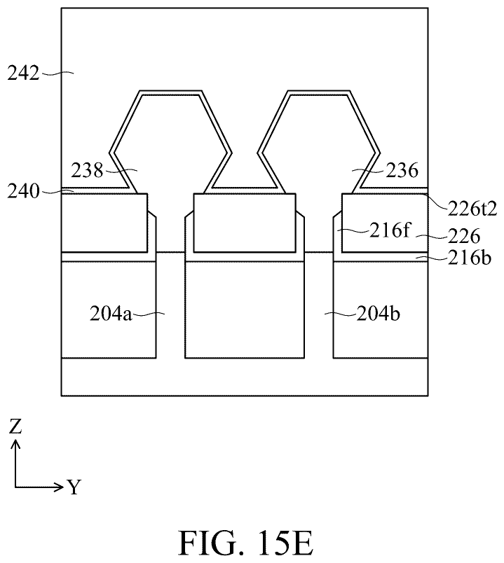

At operation 128, a contact etch stop layer (CESL) 240 and an interlayer dielectric (ILD) layer 242 are conformally formed over the semiconductor device 200, as shown in FIGS. 15 and 15A-15E. FIG. 15 is a schematic perspective view of the semiconductor device 200. FIG. 15A is a schematic sectional view of the semiconductor device 200 along A-A line in FIG. 15. FIG. 15B is a schematic sectional view of the semiconductor device 200 along B-B line in FIG. 15. FIG. 15C is a schematic sectional view of the semiconductor device 200 along C-C line in FIG. 15. FIG. 15D is a schematic sectional view of the semiconductor device 200 along D-D line in FIG. 15. FIG. 15E is a schematic view of the semiconductor device 200 according to another embodiment.

The CESL 240 is formed over exposed surfaces of the semiconductor device 200. The CESL 240 is formed on the epitaxial source/drain regions 236, 238 the protective layer 226, the gate sidewall spacers 216g, and the fin sidewall spacers 216f if not covered by the protective layer 226. The CESL 240 may include Si₃N₄, SiON, SiCN or any other suitable material, and may be formed by CVD, PVD, or ALD.

In FIGS. 15 and 15A, the fin sidewall spacers 216f are higher than the protective layer 226 and protruding over the protective layer 226. Therefore, the CESL layer 240 is in contact with the fin sidewall spacers 216f, and the source/drain regions 236, 238 are not in contact with the protective layer 226. In FIG. 15E, the fin sidewall spacers 216f are lower than the protective layer 226 and the protective layer 226 extends above the fin sidewall spacers 216f. Therefore, a portion of the protective layer 226 contacts the source/drain regions 236/238, while the CESL layer 240 is not in contact with the fin sidewall spacers 216f.

The ILD layer 242 is formed over the contact etch stop layer 240. The materials for the ILD layer 242 include compounds comprising Si, O, C, and/or H, such as silicon oxide, SiCOH and SiOC. Organic materials, such as polymers, may be used for the ILD layer 242. In some embodiments, the ILD layer 242 may be formed by flowable CVD (FCV). As shown in FIG. 15, the ILD layer 242 protects the epitaxial source/drain regions 236, 238 during the removal of the sacrificial gate structures 214.

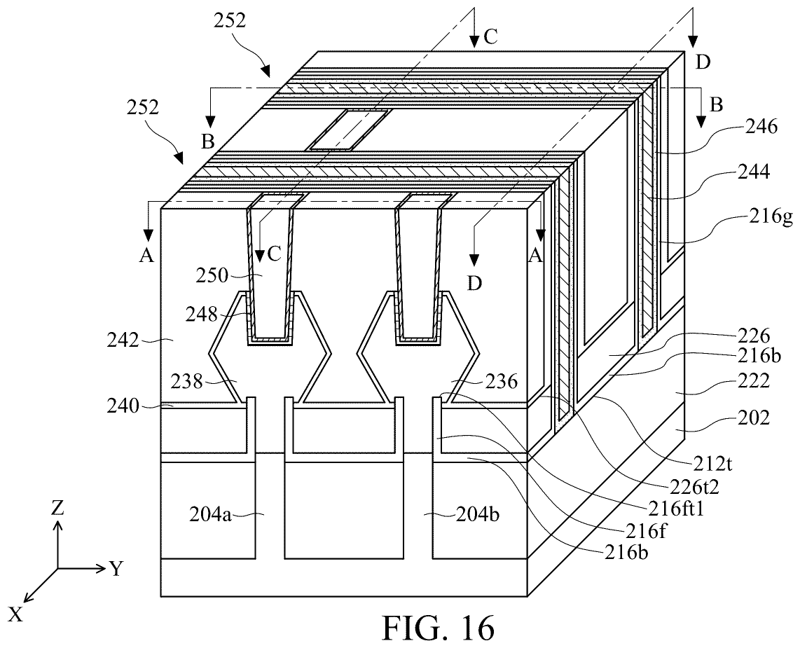

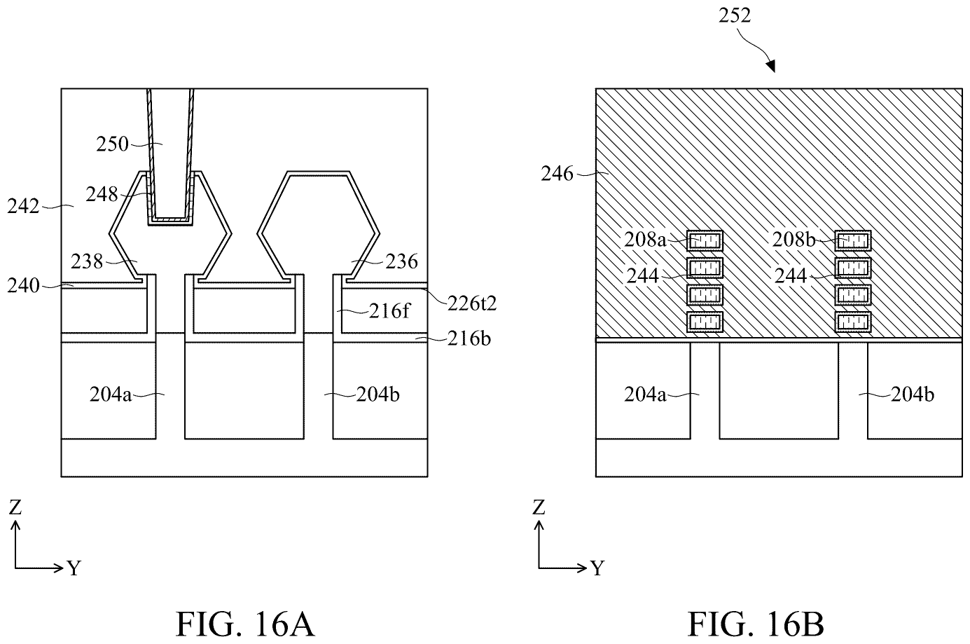

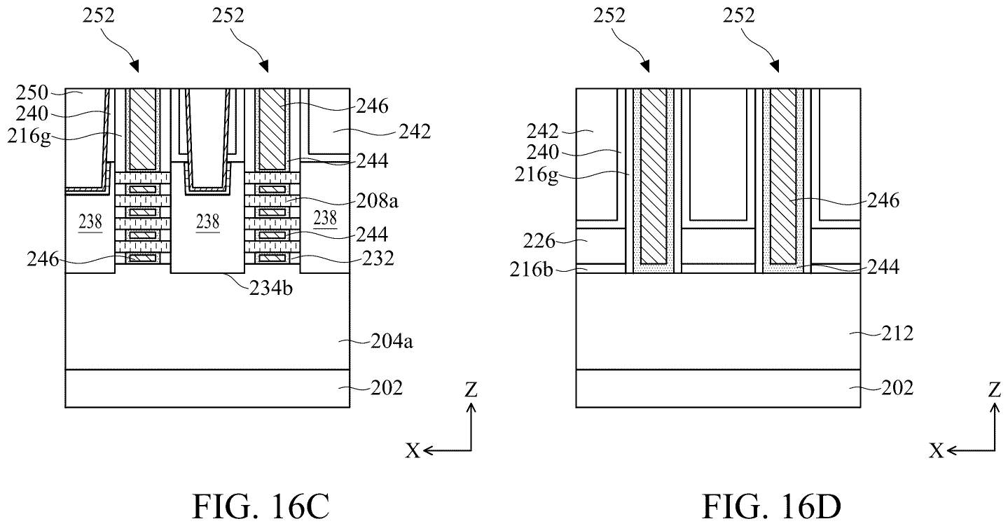

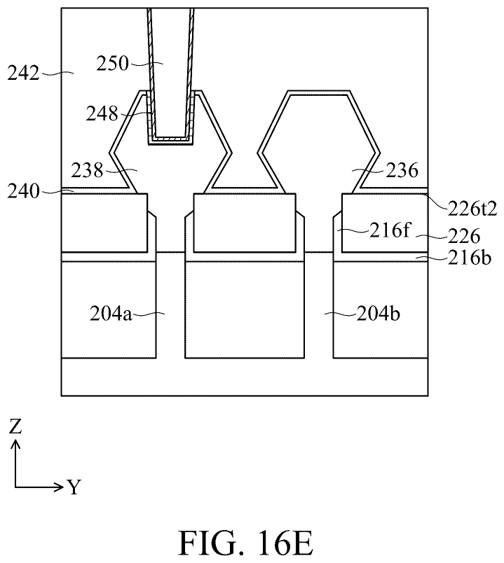

At operation 130, replacement gate structures 252 and source/drain contact features 250 are formed as shown in FIGS. 16, and 16A-16E. FIG. 16 is a schematic perspective view of the semiconductor device 200. FIG. 16A is a schematic sectional view of the semiconductor device 200 along A-A line in FIG. 16. FIG. 16B is a schematic sectional view of the semiconductor device 200 along B-B line in FIG. 16. FIG. 16C is a schematic sectional view of the semiconductor device 200 along C-C line in FIG. 16. FIG. 16D is a schematic sectional view of the semiconductor device 200 along D-D line in FIG. 16. FIG. 16E is a schematic view of the semiconductor device 200 according to another embodiment.

In some embodiments, the sacrificial gate dielectric layer 218 and the sacrificial gate electrode layer 220 are removed using dry etching, wet etching, or a combination. The semiconductor layers 206a, 206b are exposed and subsequently removed resulting in gate cavities surrounding nanosheets of the semiconductor layers 208a, 208b. Replacement gate structures 252 are then filled in the gate cavities. The replacement gate structures 252 may include a gate dielectric layer 244 and a gate electrode layer 246.

The gate dielectric layer 244 is formed on exposed surfaces in the gate cavities. The gate dielectric layer 244 may have different composition and dimensions for N-type devices and P-type devices and are formed separately using patterned mask layers and different deposition recipes. The gate dielectric layer 244 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 244 may be formed by CVD, ALD or any suitable method.

The gate electrode layer 246 is formed on the gate dielectric layer 244 to fill the gate cavities. The gate electrode layer 246 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 246 may be formed by CVD, ALD, electro-plating, or other suitable method. After the formation of the gate electrode layer 246, a planarization process, such as a CMP process, is performed to remove excess deposition of the gate electrode material and expose the top surface of the ILD layer 242.

Contact holes may be formed through the ILD layer 242, the CESL 240 to expose the epitaxial source/drain regions 236, 238, and subsequently filled with a conductive material. Suitable photolithographic and etching techniques are used to form the contact holes through various layers. After the formation of the contact holes, a silicide layer 248 is selectively formed over surfaces of the epitaxial source/drain regions 236, 238 exposed by the contact holes. The silicide layer 248 may be formed by depositing a metal source layer to cover exposed surfaces including the exposed surfaces of the epitaxial source/drain regions 236, 238 and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed. During the rapid anneal process, the portion of the metal source layer over the epitaxial source/drain regions 236, 238 reacts with silicon in the epitaxial source/drain regions 236, 238 to form the silicide layer 248. Unreacted portion of the metal source layer is then removed. In some embodiments, the silicide layer 248 includes one or more of WSi, CoSi, NiSi, TiSi, MoSi, and TaSi.

After formation of the silicide layer 248, a conductive material is deposited to fill contact holes and form the source/drain contact features 250. Optionally, a barrier layer may be formed in the contact holes prior to forming the source/drain contact features 250. In some embodiments, the conductive material layer for the gate contact may be formed by CVD, PVD, plating, ALD, or other suitable technique. In some embodiments, the conductive material for the source/drain contact features 250 includes TiN, TaN, Ta, Ti, Hf, Zr, Ni, W, Co, Cu, Ag, Al, Zn, Ca, Au, Mg, Mo, Cr, or the like. Subsequently, a CMP process is performed to remove a portion of the conductive material layer above a top surface of the ILD layer 242.

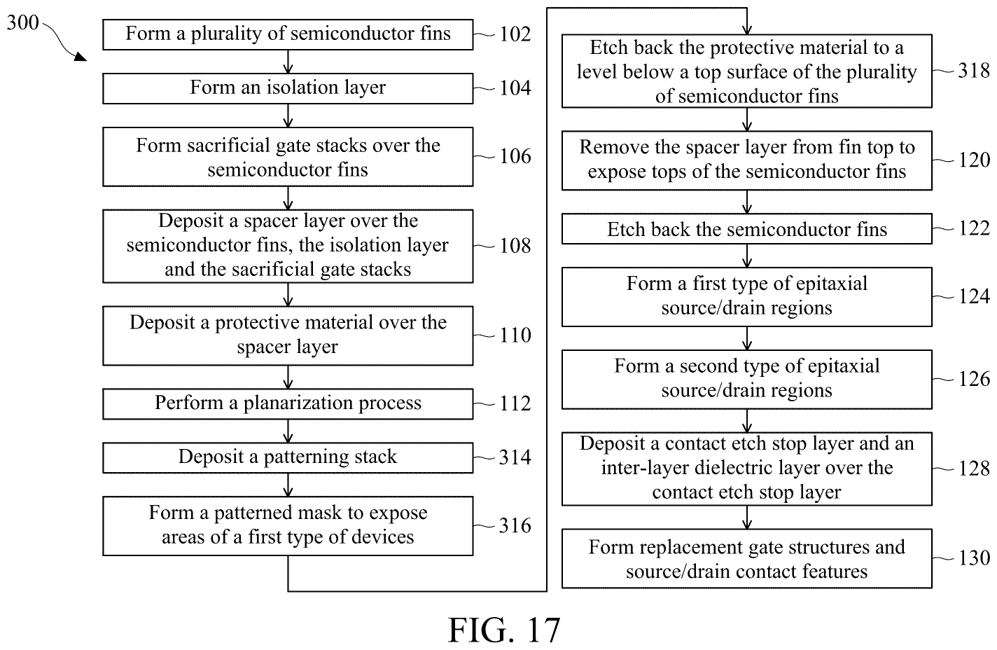

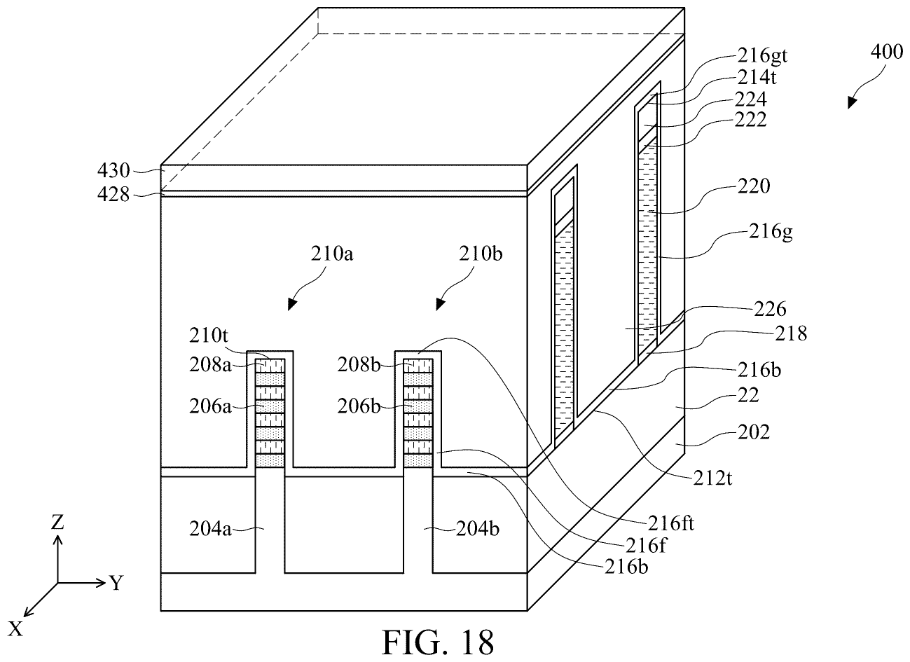

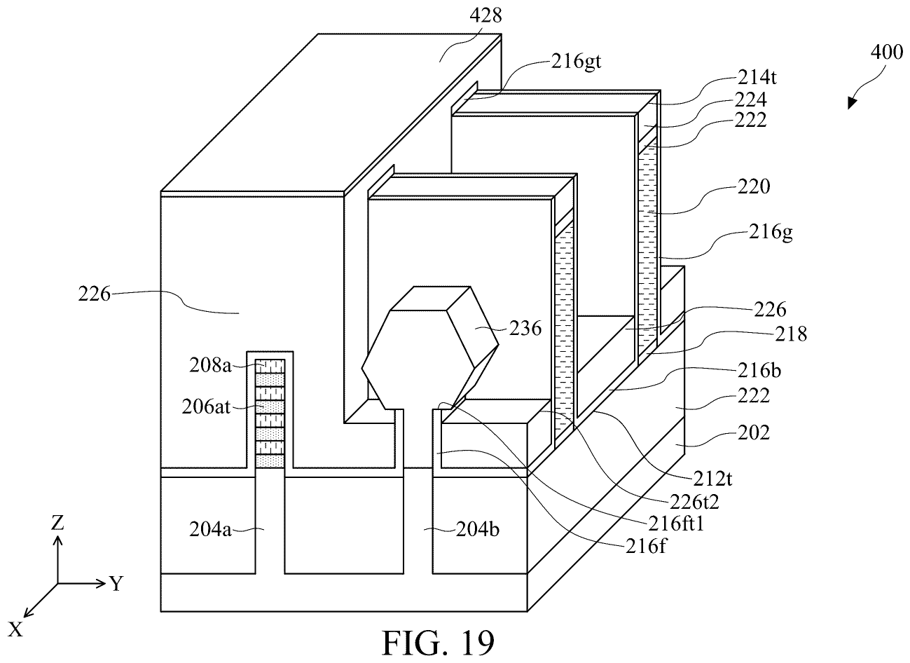

FIG. 17 is a flow chart of a method 300 for manufacturing of a semiconductor device according to embodiments of the present disclosure. FIGS. 18-19 schematically illustrate various stages of manufacturing a semiconductor device 400 according to the method 300. The method 300 is similar to the method 100 except that in method 300, the protective layer 226 according to the present disclosure is etched back after patterning process.

Similar to the method 100, the method 300 begins with operations 102-112, which is schematically demonstrated the fabrication stages in FIGS. 2-7. After the operation 112, operation 314 is performed.

In operation 314, the protective layer 226 is deposited and optionally annealed planarized, a patterning stack is deposited over the protective layer 226, as shown in FIG. 18, which is a schematic perspective view of the semiconductor device 400. In some embodiments, the pattern stack may include a mask layer 428 and a photoresist layer 430. The hard mask layer 428 is deposited over exposed surfaces of the semiconductor device 400, such as the top surface 226t0 of the protective layer 226. In some embodiments, the hard mask layer 428 may include an aluminum oxide (AlOₓ) layer. Other suitable materials capable of withstanding the processing conditions of epitaxial source/drain formation. The photoresist layer 430 is coated over the hard mask layer 428. The photoresist layer 430 may be a tri-layer photoresist. Optionally, the protective layer 226 may also function as a mask layer during the subsequent process, and the hard mask layer 428 may be omitted.

In operation 316, a photolithography process is performed to pattern the hard mask layer 428 to expose process areas, as shown in FIG. 19, which is a schematic perspective view of the semiconductor device 400. In some embodiments, the hard mask layer 428 is patterned to expose areas where a first type of devices. After the photolithography process, an ashing process is performed to remove the r photoresist layer 430, and an etch process is performed to remove the portion of the hard mask layer 428. Because the hard mask layer 428 and the photoresist layer 430 are deposited on the top surface 226t0, which is a planar surface, residual of the hard mask layer 428 and the photoresist layer 420 is minimal.

In the situation that the hard mask layer 428 is omitted, the patterned photoresist layer 430 may remain on the semiconductor device 400 after operation 318.

In operation 318, an etch back process is performed to the protective layer 226 not covered by the patterned hard mask layer 428 and/or the patterned photoresist layer 430 so that a top surface 226t1 is below the fin top spacer 226ft, as shown in FIG. 19. The etch back process may be an isotropic etching process such a dry chemical etching or wet etching, or an anisotropic etching process such as dry plasma etching. The operation 318 may be performed in similar to the operation 114 except with a patterned mask.

After the operation 318, operations 120, 122, and 124 are subsequently performed to form the epitaxial source/drain regions 236 of the first type of devices are formed, as shown in FIG. 19. Similar to described with the method 100, the protective layer 226 provides protections to the isolation layer 212 and the bottom spacers 216b during these operations along with various advantages.

In operation 126, the epitaxial source/drain regions 238 of the second type of devices are formed. In operation 126, the operations 314, 316, 318, 120, 122 may be repeated to form source/drain recesses on areas of the second type of devices. Similarly, the protective layer 226 provides protections to the isolation layer 212 and the bottom spacers 216b along with various advantages during these operations as well.

After the operations 128, 130, the semiconductor device 400 is substantially similar to the semiconductor device 200 as shown in FIGS. 16 and 16A-E.

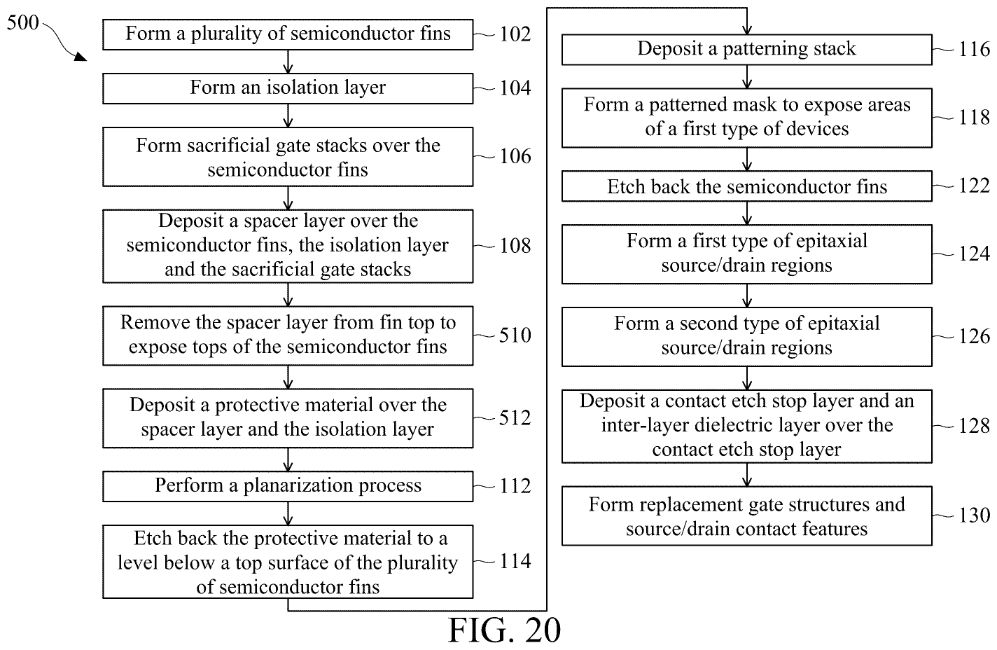

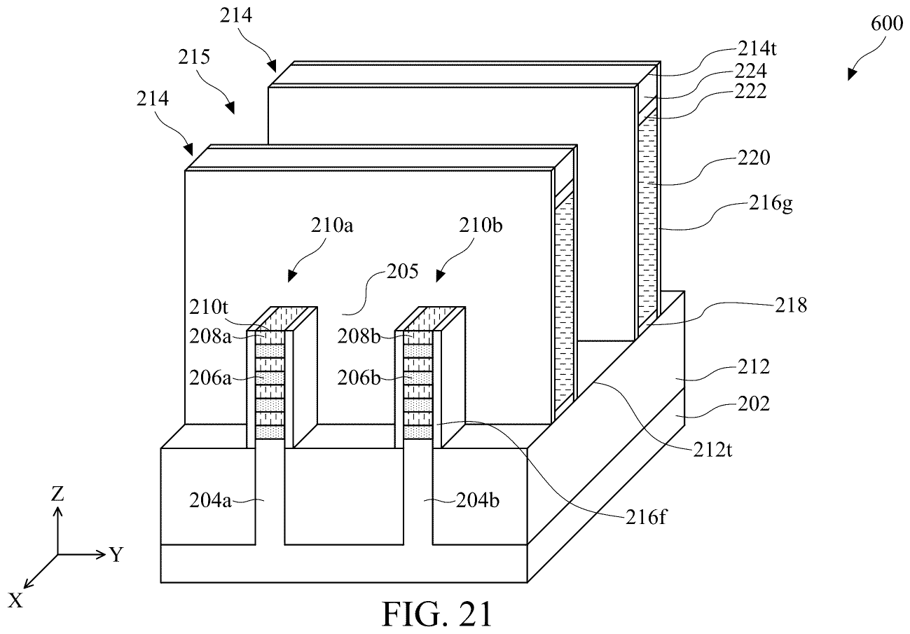

FIG. 20 is a flow chart of a method 500 for manufacturing of a semiconductor device according to embodiments of the present disclosure. FIGS. 21-23 and 23A-23B schematically illustrate various stages of manufacturing a semiconductor device 600 according to the method 500. The method 500 is similar to the method 100 except that in method 500 a protective material according to the present disclosure is deposited and etched back after the fin top spacers 216ft and the gate top spacers 216gt are removed to expose the underlying structures.

Similar to the method 100, the method 500 begins with operations 102-108, which is schematically demonstrated the fabrication stages in FIGS. 2-6. After the operation 108, operation 510 is performed.

In operation 510, an etch process is performed to remove the fin top spacers 216ft and gate top spacers 216gt to expose the top surface 210t of the fin structures 210 and the mask layer 224 respectively, as shown in FIG. 21, which is a schematic perspective view of the semiconductor device 600. In some embodiments, the fin top spacers 216ft and gate top spacers 216gt may be removed by an anisotropic etch to remove the spacer layer 216 from horizontal surfaces. As shown in FIG. 21, the bottom spacers 216b are also substantially removed exposing the top surface 212t of the isolation layer 212 to the trenches 205.

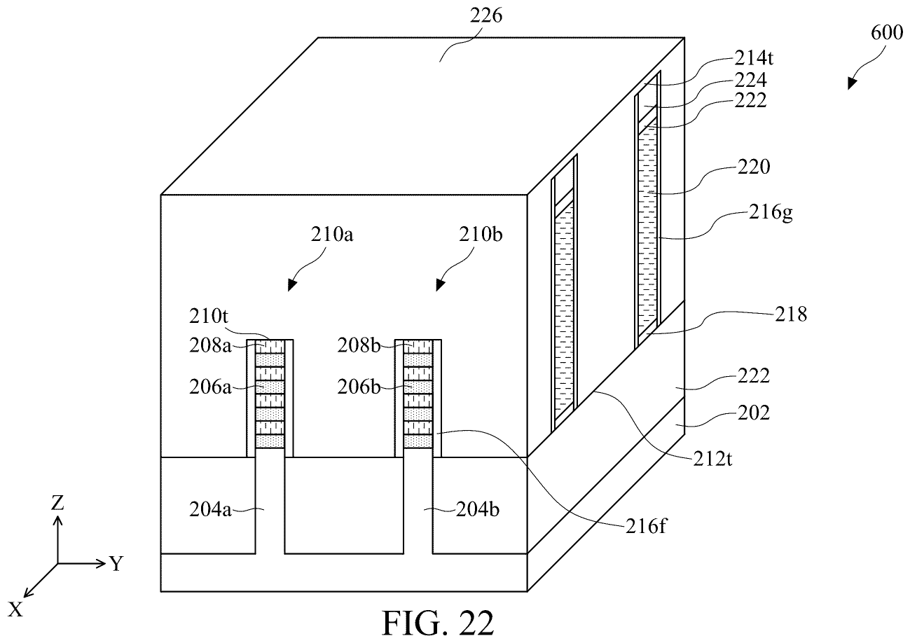

In operation 512, a protective layer 226 is deposited over the semiconductor device 600, as shown in FIG. 22, which is a schematic perspective view of the semiconductor device 600. Operation 512 may be performed similar to the operation 110 in the method 100. The protective layer 226 may be selected from materials having etch selectivity with the materials in the spacer layer 216 and the fin structures 210 so that the protective layer 226 may be used to protect underlying structures in the subsequent removal of the spacer layer 216 and the fin structures 210. The protective layer 226 is in contact with the isolation layer 212, the fin sidewall spacers 216f, the gate sidewall spacers 216g, the top surface 210t of the fin structures 210, and the top surface 214t of the sacrificial gate structures 214.

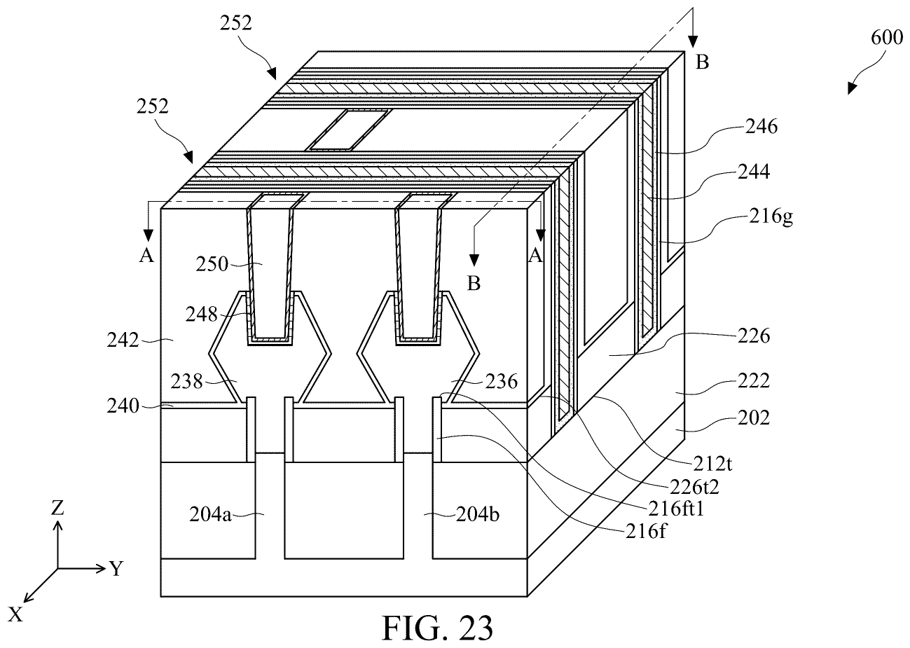

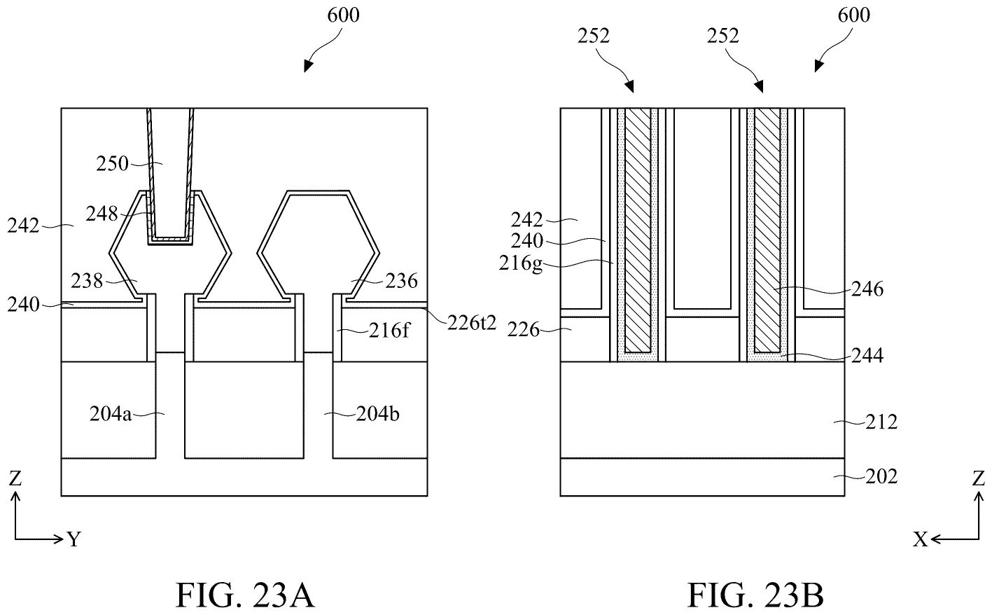

After the operation 512, operations 112, 114, 116, 118, 122, 124, 126, 128, and 130 are subsequently performed to form the semiconductor device 600, as shown in FIG. 23, 23A-23B. FIG. 23 is a schematic perspective view of the semiconductor device 600. FIG. 23A is a schematic sectional view of the semiconductor device 600 along A-A line in FIG. 23. FIG. 23B is a schematic sectional view of the semiconductor device 600 along B-B line in FIG. 23.

Similar to described with the method 100, the protective layer 226 provides protections to the isolation layer 212 during these operations along with various advantages while fabricating the semiconductor device 600 using the method 500. The semiconductor device 600 is similar to the semiconductor device 200 except that the semiconductor device 600 does not include the bottom spacers 216b. In the semiconductor device 600, the protective layer 226 is in contact with the isolation layer 212 at the top surface 212t.

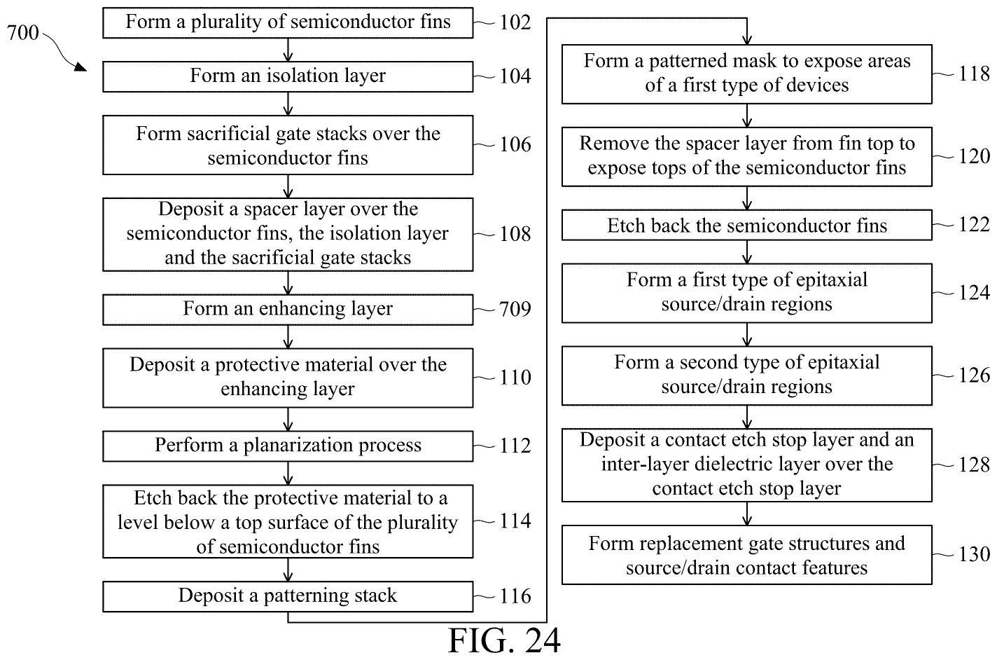

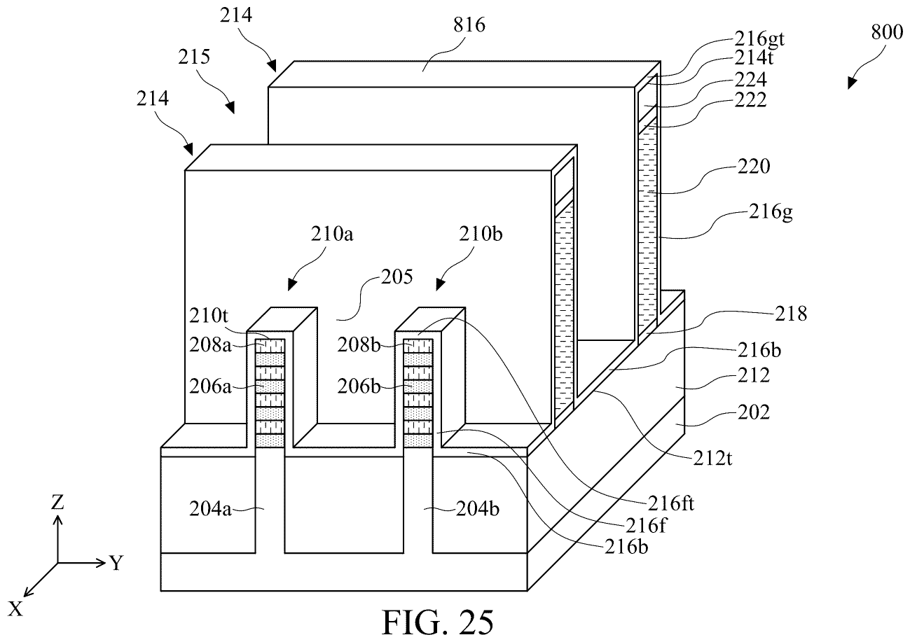

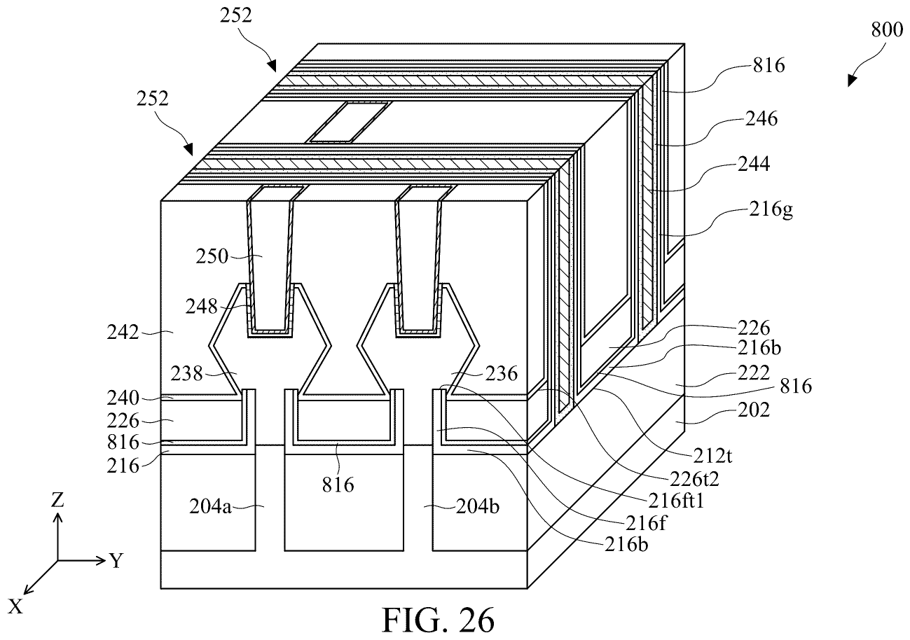

FIG. 24 is a flow chart of a method 700 for manufacturing of a semiconductor device according to embodiments of the present disclosure. FIGS. 25-26 schematically illustrate various stages of manufacturing a semiconductor device 800 using the method 700. The method 700 is similar to the method 100 except that in method 700 an enhancing layer is deposited over the spacer layer 216 prior to depositing a protective material according to the present disclosure.

Similar to the method 100, the method 700 begins with operations 102-108, which is schematically demonstrated the fabrication stages in FIGS. 2-6. After the operation 108, operation 709 is performed to deposit an enhancing layer.

In operation 709, an enhancing layer 816 is deposited over the spacer layer 216, as shown in FIG. 25, which is a perspective view of the semiconductor device 800. The enhancing layer 816 may be formed by a blanket deposition. In some embodiments, the enhancing layer 816 is configured to strength the spacer layer 216. The spacer layer 216 may be strengthened to obtain a greater etch resistivity and/or a greater mechanical strength to withstand the subsequent processes and to improve structures in the resulting semiconductor device 800.

In some embodiments, the enhancing layer 816 may include a metal or a metal oxide. In some embodiments, the enhancing layer 816 may include aluminum, copper, titanium, tantalum, tungsten, cobalt, molybdenum, ruthenium, an alloy thereof, or a combination thereof, which is formed by CVD, ALD, electro-plating, or other suitable method. In other embodiments, the enhancing layer 816 may include one or more metal oxides, such as HfO₂, HfSiO, HfSiON, HfTaO, HfTiO, HfZrO, zirconium oxide, aluminum oxide, titanium oxide, lanthanum oxide, yttrium oxide, hafnium dioxide-alumina (HfO₂—Al₂O₃) alloy, and/or combinations thereof, which may be formed by CVD, ALD or any suitable method. In some embodiments, the enhancing layer 816 may have a thickness in a range between about 0.1 nm and about 5 nm.

After the operation 709, operations 110-130 are subsequently performed to form the semiconductor device 800, as shown in FIG. 26. FIG. 26 is a schematic perspective view of the semiconductor device 800. Similar to described with the method 100, the protective layer 226 provides protections to the isolation layer 212, the bottom spacers 216b, and the fin sidewall spacers 216f during these operations along with various advantages while fabricating the semiconductor device 800 using the method 700. The semiconductor device 800 is similar to the semiconductor device 200 except that the semiconductor device 800 includes the enhancing layer 816 on the bottom spacers 216b, the fin sidewall spacers 216f, and the gate sidewall spacers 216g. In the semiconductor device 800, the protective layer 226 is in contact with the enhancing layer 816.

Even though embodiments described above related to fabrication of GAA devices, embodiments of the present disclosure may be used to provide protection of bottom structures of any suitable devices, for example, FinFET device, complementary FET (CFET), and the like.

Various embodiments or examples described herein offer multiple advantages over the state-of-art technology. The protective layer according to the present disclosure prevents STI loss and bottom spacer loss, thus, avoiding structure damages, reducing leaks, and improving device performance. The protective layer according to the present disclosure improves process uniformity by also eliminate process loading or non-uniformity in the STI loss, fin sidewall spacer height, and recess profiles. The protective layer may also slow down fin sidewall spacer etching rate during semiconductor fin etch back, thus, improving source/drain regions profile control.

Some embodiments of the present provide a method for fabricating a semiconductor device, comprising: forming a first device feature on a semiconductor substrate; forming a second device feature on the semiconductor substrate, wherein the first device feature is adjacent the second device feature, and the second device feature is taller than the first device feature relative to the semiconductor substrate; depositing a protective layer over the first device feature and the second device feature; etching back the protective layer to reveal a portion of the second device feature while the first device feature remains covered by the protective layer; and etching the second device feature to form an opening below a top surface of the protective layer.

Some embodiments of the present disclosure provide a method for fabricating a semiconductor device, comprising: forming a first fin structure and a second fin structure over a semiconductor substrate; forming an isolation layer around lower portions of the first and second fin structures; forming a sacrificial gate structure over the first and second fin structures and the isolation layer; depositing a spacer layer over the isolation layer, the first and second fin structures, and the sacrificial gate structure; immersing the first and second fin structures and the sacrificial gate structure in a protective layer; etching back the protective layer so that a top surface of the protective layer is below a top surface of the first fin structure; and recess etching the first fin structure while the isolation layer is covered by the protective layer.

Some embodiments of the present disclosure provide a semiconductor device, comprising: a fin structure; a source/drain region in contact with the fin structure; a gate structure disposed over the fin structure; a gate sidewall spacer layer disposed on a sidewall of the gate structure and in contact with the source/drain region; an isolation layer disposed around the fin structure; a contact etch stop layer (CESL) disposed on the source/drain region; an interlayer dielectric layer (IDL) disposed on the CESL; and a bottom spacer disposed on the isolation layer and connected to the gate sidewall spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure on a substrate;
depositing an isolation layer over the fin structure and the substrate;
etching back the isolation layer so that the isolation layer is disposed around a lower portion of the fin structure;
forming a gate structure over the fin structure;
depositing a protective layer over the fin structure and the isolation layer;
etching back the protective layer to reveal a portion of the fin structure while the isolation layer remains covered by the protective layer;
etching the fin structure to form an opening below a top surface of the protective layer;
forming a source/drain region in the opening; and
depositing a contact etch stop layer the source/drain region and the protective layer.

2. The method of claim 1, further comprising planarizing the protective layer prior to etching back the protective layer.

3. The method of claim 1, further comprising annealing the protective layer prior to etching back the protective layer.

4. The method of claim 1, further comprising depositing a spacer layer over the fin structure and the gate structure prior to depositing the protective layer.

5. The method of claim 4, further comprising removing a portion of the spacer layer deposited on a top surface of the fin structure.

6. The method of claim 5, wherein removing the portion of the spacer layer is performed after etching back of the protective layer.

7. The method of claim 5, wherein removing the portions of the spacer layer is performed prior to depositing the protective layer.

8. The method of claim 1, further comprising:
depositing a pattern stack over the protective layer prior to etching back the protective layer.

9. The method of claim 1, further comprising:
depositing a pattern stack over the protective layer after etching back the protective layer.

10. A method for fabricating a semiconductor device, comprising:
forming a fin structure over a semiconductor substrate;
forming an isolation layer around lower portions of the fin structure;
forming a sacrificial gate structure over the fin structure and the isolation layer;
depositing a spacer layer over the isolation layer, the fin structure, and the sacrificial gate structure;
immersing the fin structure and the sacrificial gate structure in a protective layer;
performing a first etching process to etch back the protective layer to a first level, wherein the protective layer is below the fin structure;
performing a second etch process to etch back the fin structure and the protective layer, wherein the protect layer is etched to a second level below the first level, and the fin structure is below the protective layer;
forming a source/drain region from the fin structure; and
depositing a contact etch stop layer on the source/drain region and the protective layer.

11. The method of claim 10, further comprising:
prior to recess etching the fin structure, forming a pattern the protective layer to expose the fin structure.

12. The method for claim 11, wherein forming the pattern is performed prior to performing the first etching process.

13. The method of claim 11, wherein forming the pattern is performed after performing the first etching process.

14. The method of claim 11, further comprising depositing an enhancing layer over the spacer layer.

15. A semiconductor device, comprising:
an isolation region disposed on a substrate;
a channel region protruding over the isolation region;
a gate structure disposed on the channel region and the isolation region;
a source/drain region connected to the channel region;
a spacer layer comprising:
a sidewall portion disposed between the gate structure and the source/drain region; and
a bottom portion disposed on the isolation region; and
a protective layer disposed on the bottom portion of the spacer layer.

16. The semiconductor device of claim 15, further comprising:
a contact etch stop layer (CESL) disposed on the source/drain region and the protective layer; and
an interlayer dielectric layer (IDL) disposed on the CESL.

17. The semiconductor device of claim 16, wherein the spacer layer further comprising a fin sidewall portion disposed between the source/drain region and the protective layer.

18. The semiconductor device of claim 17, wherein a top surface of the protective layer is lower than the fin sidewall portion of the spacer layer.

19. The semiconductor device of claim 17, wherein a top surface of the protective layer is above the fin sidewall portion of the spacer layer, and the protective layer is in contact with the source/drain region.

20. The semiconductor device of claim 15, further comprising an enhancing layer disposed on the spacer layer.
